(19) United States
(12) Patent Application Publication
(10) Pub. No.: US 2025/0072150 A1
(43) Pub. Date: Feb. 27, 2025

(54) IMAGING ELEMENT AND METHOD OF MANUFACTURING IMAGING ELEMENT

(71) Applicant: SONY SEMICONDUCTOR SOLUTIONS CORPORATION, Kanagawa (JP)

(72) Inventor: Hideto HASHIGUCHI, Kumamoto (JP)

(73) Assignee: SONY SEMICONDUCTOR SOLUTIONS CORPORATION, Kanagawa (JP)

(21) Appl. No.: 18/725,906

(22) PCT Filed: Nov. 18, 2022
(86) PCT No.: PCT/JP2022/042802

§ 371 Date: Jul. 1, 2024

(30) Foreign Application Priority Data
Jan. 11, 2022 (JP) 2022-002479

(51) Int. Cl. H01L 27/146

(52) U.S. Cl. CPC H01L 27/14636; H01L 27/14634; H01L 27/1469

(57) ABSTRACT

An imaging element according to one embodiment of the present disclosure includes a wiring layer including a plurality of wirings extending in one direction, a barrier film laminated on the wiring layer and having an end surface above one of the plurality of wirings, a first insulating film laminated on the wiring layer and the barrier film, a first air gap provided between the plurality of wirings adjacent to each other by the first insulating film, and a second air gap provided above the first air gap.

### TECHNICAL FIELD

The present disclosure relates, for example, to an imaging element having an air gap between each wiring and a method of manufacturing an imaging element.

### BACKGROUND ART

In a semiconductor device, along with a miniaturization of a semiconductor integrated circuit element, a wiring that couples between and within each element has become smaller in spacing. In response to this, for example, PTL 1 discloses a semiconductor device having an air gap (air gap) between wirings to reduce a capacitance between each wiring.

### CITATION LIST

### Patent Literature

PTL 1: Japanese Unexamined Patent Application Publication No. 2008-193104

### SUMMARY OF THE INVENTION

Meanwhile, a laminated type of image sensor has become more common in recent years and is expected to reduce wiring capacitance.

It is desirable to provide an imaging element and a method of manufacturing an imaging element that enables a reduction in wiring capacitance.

An imaging element according to one embodiment of the present disclosure includes: a wiring layer including a plurality of wirings, the plurality of wirings extending in one direction; a barrier film laminated on the wiring layer, the barrier film having an end surface above one of the plurality of wirings; and a first insulating film laminated on the wiring layer and the barrier film. The imaging element has a first air gap between the plurality of wirings adjacent to each other, the first air gap being provided by the first insulating film, and a second air gap provided above the first air gap.

A first method of manufacturing an imaging element according to one embodiment of the present disclosure includes: forming a wiring layer including a plurality of wirings, the plurality of wirings extending in one direction; forming a first barrier film on the wiring layer; causing the wiring layer to have a first opening in a predetermined region thereof, the wiring layer having the first opening between the barrier film and the plurality of wirings adjacent to each other; forming a first insulating film, thereby forming a first air gap between the plurality of wirings adjacent to each other; and forming a third insulating film, thereby forming a second air gap above the first air gap.

A second method of manufacturing an imaging element according to one embodiment of the present disclosure includes: forming a wiring layer including a plurality of wirings, the plurality of wirings having a side surface and a bottom surface covered by a barrier metal and extending in one direction; forming a first barrier film on the wiring layer; causing the wiring layer to have a first opening while partially retracting the barrier metal in a predetermined region of the wiring layer, the wiring layer having the first opening between the barrier film and the plurality of wirings adjacent to each other, and the barrier metal covering the side surface of the plurality of wirings exposed by the first opening; forming a second insulating film, the second insulating film covering an upper surface and a side surface of the plurality of wirings; and forming a first insulating film, thereby forming a first air gap and further forming a second air gap, the first air gap being formed between the plurality of wirings adjacent to each other, and the second air gap being formed above the first air gap.

In the imaging element according to one embodiment of the present disclosure, the first method of manufacturing an imaging element according to one embodiment of the present disclosure, and the second method of manufacturing an imaging element according to one embodiment of the present disclosure, the plurality of wirings extending in one direction is formed to have a first air gap therebetween and further to have a second air gap above the first air gap. A capacitance between each wiring extending in one direction is thereby reduced.

### BRIEF DESCRIPTION OF DRAWINGS

FIG. 1 is a schematic view illustrating an example of a vertical cross-sectional configuration of a wiring structure according to a first embodiment of the present disclosure.

FIG. 2A is a schematic view illustrating an example of a horizontal cross-sectional configuration of the wiring structure illustrated in FIG. 1.

FIG. 2B is a schematic view illustrating an example of the horizontal cross-sectional configuration of the wiring structure illustrated in FIG. 1.

FIG. 3A is a schematic cross-sectional view illustrating an example of a manufacturing process for the wiring structure illustrated in FIG. 1.

FIG. 3B is a schematic cross-sectional view illustrating an example of a manufacturing process following FIG. 3A.

FIG. 3C is a schematic cross-sectional view illustrating an example of a manufacturing process following FIG. 3B.

FIG. 3D is a schematic cross-sectional view illustrating an example of a manufacturing process following FIG. 3C.

FIG. 3E is a schematic cross-sectional view illustrating an example of a manufacturing process following FIG. 3D.

FIG. 3F is a schematic cross-sectional view illustrating an example of a manufacturing process following FIG. 3E.

FIG. 3G is a schematic cross-sectional view illustrating an example of a manufacturing process following FIG. 3F.

FIG. 4 illustrates an example of a vertical cross-sectional configuration of an imaging element according to a first embodiment of the present disclosure.

FIG. 5 illustrates an example of a schematic configuration of the imaging element illustrated in FIG. 4.

FIG. 6 is a diagram in which the wiring structure illustrated in FIG. 1 is applied to the imaging element illustrated in FIG. 4.

FIG. 7 illustrates an example of a sensor pixel and a readout circuit illustrated in FIG. 4.

FIG. 8 illustrates an example of the sensor pixel and the readout circuit illustrated in FIG. 4.

FIG. 9 illustrates an example of the sensor pixel and the readout circuit illustrated in FIG. 4.

FIG. 10 illustrates an example of the sensor pixel and the readout circuit illustrated in FIG. 4.

FIG. 11 illustrates an example of a coupling mode between a plurality of readout circuits and a plurality of vertical signal lines.

FIG. 12 illustrates an example of a horizontal cross-sectional configuration of the imaging element illustrated in FIG. 4.

FIG. 13 illustrates an example of a horizontal cross-sectional configuration of the imaging element illustrated in FIG. 4.

FIG. 14 illustrates an example of a wiring layout in a horizontal plane of the imaging element illustrated in FIG. 4.

FIG. 15 illustrates an example of a wiring layout in a horizontal plane of the imaging element illustrated in FIG. 4.

FIG. 16 illustrates an example of a wiring layout in a horizontal plane of the imaging element illustrated in FIG. 4.

FIG. 17 illustrates an example of the wiring layout in a horizontal plane of the imaging element illustrated in FIG. 4.

FIG. 18A illustrates an example of a manufacturing process for the imaging element illustrated in FIG. 4.

FIG. 18B illustrates an example of a manufacturing process following FIG. 18A.

FIG. 18C illustrates an example of a manufacturing process following FIG. 18B.

FIG. 18D illustrates an example of a manufacturing process following FIG. 18C.

FIG. 18E illustrates an example of a manufacturing process following FIG. 18D.

FIG. 18F illustrates an example of a manufacturing process following FIG. 18E.

FIG. 18G illustrates an example of a manufacturing process following FIG. 18F.

FIG. 19 is a schematic view illustrating an example of a vertical cross-sectional configuration of a wiring structure according to a second embodiment of the present disclosure.

FIG. 20A is a schematic cross-sectional view illustrating an example of a manufacturing process for the wiring structure illustrated in FIG. 19.

FIG. 20B is a schematic cross-sectional view illustrating an example of a manufacturing process following FIG. 20A.

FIG. 20C is a schematic cross-sectional view illustrating an example of a manufacturing process following FIG. 20B.

FIG. 21 is a schematic view illustrating an example of a vertical cross-sectional configuration of a wiring structure according to a third embodiment of the present disclosure.

FIG. 22A is a schematic cross-sectional view illustrating an example of a manufacturing process for the wiring structure illustrated in FIG. 21.

FIG. 22B is a schematic cross-sectional view illustrating an example of a manufacturing process following FIG. 22A.

FIG. 22C is a schematic cross-sectional view illustrating an example of a manufacturing process following FIG. 22B.

FIG. 23 is a schematic view illustrating an example of a vertical cross-sectional configuration of a wiring structure according to modification example 1 of the present disclosure.

FIG. 24 is a schematic view illustrating another example of the vertical cross-sectional configuration of the wiring structure according to modification example 1 of the present disclosure.

FIG. 25 illustrates an example of a vertical cross-sectional configuration of an imaging element according to modification example 2 of the present disclosure.

FIG. 26 illustrates an example of a vertical cross-sectional configuration of an imaging element according to modification example 3 of the present disclosure.

FIG. 27 illustrates an example of a horizontal cross-sectional configuration of an imaging element according to modification example 4 of the present disclosure.

FIG. 28 illustrates another example of a horizontal cross-sectional configuration of the imaging element according to modification example 4 of the present disclosure.

FIG. 29 illustrates an example of a horizontal cross-sectional configuration of an imaging element according to modification example 5 of the present disclosure.

FIG. 30 illustrates an example of a horizontal cross-sectional configuration of an imaging element according to modification example 6 of the present disclosure.

FIG. 31 illustrates an example of a horizontal cross-sectional configuration of an imaging element according to modification example 7 of the present disclosure.

FIG. 32 illustrates another example of a horizontal cross-sectional configuration of an imaging element according to modification example 8 of the present disclosure.

FIG. 33 illustrates another example of a horizontal cross-sectional configuration of the imaging element according to modification example 8 of the present disclosure.

FIG. 34 illustrates an example of a circuit configuration of the imaging element according to modification example 8 of the present disclosure.

FIG. 35 illustrates an example of a configuration in which the imaging element of FIG. 34 includes three laminated substrates according to modification example 9 of the present disclosure.

FIG. 36 illustrates an example in which a logic circuit according to modification example 10 of the present disclosure is formed separately on a substrate including a sensor pixel and a substrate including a readout circuit.

FIG. 37 illustrates an example in which a logic circuit according to modification example 11 of the present disclosure is formed on a third substrate.

FIG. 38 illustrates an example of a schematic configuration of an imaging system including an imaging element according to the above embodiments, etc.

FIG. 39 illustrates an example of an imaging procedure in the imaging system of FIG. 38.

FIG. 40 illustrates an overview of a configuration example of a solid-state imaging element of a non-laminated type and of a solid-state imaging element of a laminated type to which a technique of the present disclosure is applicable.

FIG. 41 is a cross-sectional view illustrating a first configuration example of a solid-state imaging element of a laminated type.

FIG. 42 is a cross-sectional view illustrating a second configuration example of a solid-state imaging element of a laminated type.

FIG. 43 is a cross-sectional view illustrating a third configuration example of a solid-state imaging element of a laminated type.

FIG. 44 is a cross-sectional view illustrating another configuration example of a solid-state imaging element of a laminated type to which the technique of the present disclosure is applicable.

FIG. 45 is a block diagram depicting an example of schematic configuration of a vehicle control system.

FIG. 46 is a diagram of assistance in explaining an example of installation positions of an outside-vehicle information detecting section and an imaging section.

FIG. 47 is a view depicting an example of a schematic configuration of an endoscopic surgery system.

FIG. 48 is a block diagram depicting an example of a functional configuration of a camera head and a camera control unit (CCU).

### MODES FOR CARRYING OUT THE INVENTION

In the following, some embodiments of the present disclosure will be described in detail with reference to the drawings. The embodiments described below are specific examples of the present disclosure, and the present disclosure is not limited to the following embodiments. In addition, the arrangement, dimensions, dimension ratios, and the like of components in the present disclosure are not limited to the embodiment illustrated in each drawing. It is to be noted that the description will be given in the following order.
1. First Embodiment (Example of a wiring structure having a further minute air gap above an air gap formed between each adjacent wiring)
   1-1. Configuration of Wiring Structure
   1-2. Method of Manufacturing Wiring Structure
   1-3. Configuration of Imaging Element
   1-4. Method of Manufacturing Imaging Element
   1-5. Workings and Effects
2. Second Embodiment (Another example of a manufacturing method for a minute air gap above an air gap)
3. Third embodiment (Another example of a manufacturing method for a minute air gap above an air gap)
4. Modification Examples
   4-1. Modification Example 1 (Another example of an air gap shape)
   4-2. Modification Example 2 (Example using a flat-type TG)
   4-3. Modification Example 3 (Example using Cu—Cu bonding at an outer edge of a panel)
   4-4. Modification Example 4 (Example in which an offset is provided between a sensor pixel and a readout circuit)
   4-5. Modification Example 5 (Example in which a silicon substrate on which the readout circuit is provided has an island shape)
   4-6. Modification Example 6 (Example in which a silicon substrate on which the readout circuit is provided has an island shape)
   4-7. Modification Example 7 (Example in which eight sensor pixels share one FD)
   4-8. Modification Example 8 (Example in which a column signal processing circuit includes a general column ADC circuit)
   4-9. Modification Example 9 (Example in which an imaging element includes three laminated substrates)
   4-10. Modification Example 10 (Example in which a logic circuit is provided on a first substrate and a second substrate)
   4-11. Modification Example 11 (Example in which a logic circuit is provided on a third substrate)
5. Application Examples
6. Practical Application Examples

### First Embodiment

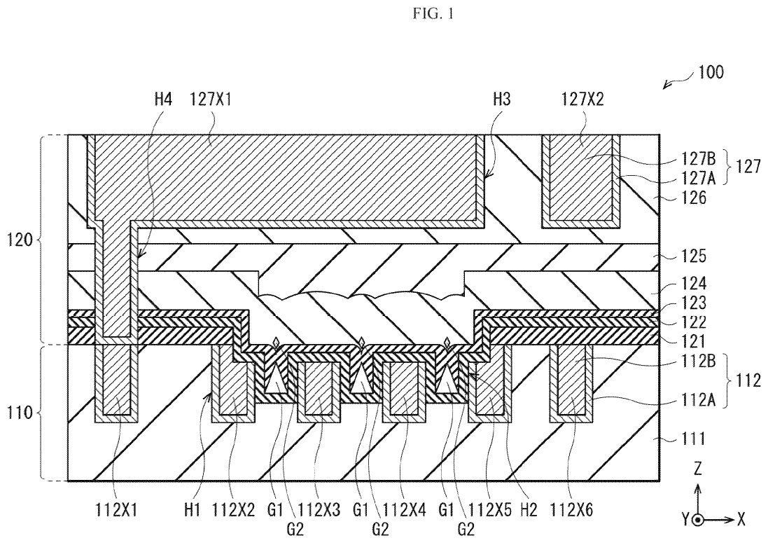

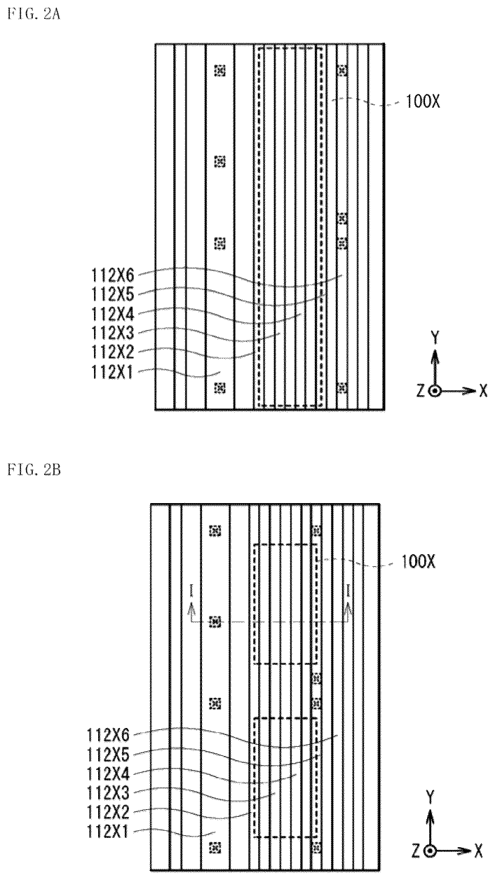

FIG. 1 schematically illustrates an example of a vertical cross-sectional configuration of a wiring structure (wiring structure 100) according to a first embodiment of the present disclosure. FIG. 2A schematically illustrates an example of a horizontal cross-sectional configuration of the wiring structure 100 illustrated in FIG. 1. FIG. 2B schematically illustrates another example of the horizontal cross-sectional configuration of the wiring structure 100 illustrated in FIG. 1. In addition, for example, FIG. 1 corresponds to a cross section taken along line I-I as illustrated in FIG. 2B. For example, the wiring structure 100 has a multilayer wiring configuration in which a plurality of wiring layers is laminated, and is applicable to an imaging element 1 described later, for example.

The wiring structure 100 includes a wiring layer 112 including a plurality of wirings (for example, a wiring 112X1 to a wiring 112X6) extending in one direction (for example, in a Y-axis direction), and includes a barrier film 121 and insulating films 123 and 124 that are laminated on the wiring layer 112 in order. For example, the barrier film 121 extends over the wiring layer 112 and has an end surface S121, for example, on each of the wiring 112X2 and the wiring 112X5. The insulating film 123 is laminated above the barrier film 121 and is also provided to fill an opening H2 created between adjacent wirings (for example, between adjacent wirings 112X2 and 112X3, between the wiring 112X3 and the wiring 112X4, and between the wiring 112X4 and the wiring 112X5). The insulating film 124 is laminated on the insulating film 123.

In the present embodiment, in the opening H2 described above, the wiring structure 100 has an air gap G1, one each between adjacent wirings, that is, between the wiring 112X2 and the wiring 112X3, between the wiring 112X3 and the wiring 112X4, and between the wiring 112X4 and the wiring 112X5, and further, above the air gap G1, has an air gap G2 having a smaller volume than the air gap G1. These plurality of wirings 112X1 to 112X6 and the wiring layer 112 correspond respectively to one specific example of a “plurality of wirings” and a “wiring layer” of the present disclosure. The barrier film 121 corresponds to one specific example of a “barrier film” of the present disclosure. The insulating film 123 corresponds to one specific example of a “first insulating film” of the present disclosure, and the insulating film 124 corresponds to one specific example of a “third insulating film” of the present disclosure. The air gap G1 corresponds to one specific example of a “first air gap” of the present disclosure, and the air gap G2 corresponds to one specific example of a “second air gap” of the present disclosure.

### (1-1. Configuration of Wiring Structure)

For example, the wiring structure 100 has a configuration in which a first layer 110 and a second layer 120 are laminated in this order on a silicon substrate (not illustrated) or the like. The first layer 110 has an insulating film 111 and a wiring layer 112 in which a plurality of wirings (for example, the wiring 112X1 to the wiring 112X6) is buried in the insulating film 111. The second layer 120 includes, for example, the barrier film 121, insulating films 122 to 126, and, for example, a conductive layer 127 buried in a portion of the insulating film 126.

The first layer 110 includes a plurality of wirings (for example, the wiring 112X1 to the wiring 112X6) buried in the insulating film 111.

For example, the insulating film 111 is formed using a low dielectric constant material (low-k material) having a relative permittivity (k) of 3.0 or less. Specifically, as a material for the insulating film 111, for example, it is possible to name carbon-containing silicon oxide (SiOC), SiOCH, porous silica, fluorine-doped silicon oxide (SiOF), inorganic SOG, organic SOG and organic polymer such as polyarylether, or the like.

For example, the wiring layer 112 includes a plurality of wirings extending in one direction, for example, the wiring 112X1 to the wiring 112X6 extending in a Y-axis direction. For example, the wiring 112X1 to the wiring 112X6 are formed in parallel at Line(L)/Space(S)=40-200 nm/40-200 nm. The wiring 112X1 to the wiring 112X6 are buried in an opening H1 created in the insulating film 111, and each include, for example, a barrier metal 112A formed on a side surface and a bottom surface of the opening H1 and a metal film 112B formed to fill the opening H1. As a material for the barrier metal 112A, for example, it is possible to name Ti (titanium) or Ta (tantalum) alone, or a nitride or alloy thereof. As a material for the metal film 112B, for example, it is possible to name a metallic material that mainly includes a low-resistance metal such as Cu (copper), W (tungsten), or aluminum (Al).

Furthermore, the first layer 110 has the opening H2 between each adjacent wiring, specifically, for example, in the insulating film 111 between the wiring 112X2 and the wiring 112X3, between the wiring 112X3 and the wiring 112X4, and between the wiring 112V4 and the wiring 112X5.

In the second layer 120, the barrier film 121 and a plurality of insulating films (insulating films 122-126) are laminated, and, for example, a conductive layer 127 is buried in a top layer of the insulating film 126. Specifically, from the first layer 110 side, the barrier film 121, the insulating film 122, the insulating film 123, the insulating film 124, the insulating film 125, and the insulating film 126 are laminated in this order. The above-described opening H2 created between the wiring 112X2 and the 112X3, between the wiring 112X3 and the 112X4, and between the wiring 112V4 and the 112X5 is closed by the insulating film 123 included in the second layer 120. This results in the formation of the air gap G1 that reduces a capacitance between parallel wirings, one each between the wiring 112X2 and the wiring 112X3, between the wiring 112X3 and the wiring 112X4, and between the wiring 112V4 and the wiring 112X5. For example, as illustrated in FIGS. 2A and 2B, the air gap G1 is formed across all (FIG. 2A) or a part (FIG. 2B) of a region between the wiring 112X2 and the wiring 112X3, between the wiring 112X3 and the wiring 112X4, and between the wiring 112V4 and the wiring 112X5 (air gap formation region 100X). Not limited to this, as illustrated in FIG. 2, it is possible to form the air gap G1 between other wirings extending in the Y-axis direction in addition to the wiring 112X1 to the wiring 112X6, other than forming the air gap G1 between the wiring 112X2 and the wiring 112X3, between the wiring 112X3 and the wiring 112X4, and between the wiring 112V4 and the 112X5.

For example, the barrier film 121 is intended to prevent diffusion of copper (Cu) and ingress of water in a case where the wiring 112X1 to the wiring 112X6 are formed using copper (Cu). The barrier film 121 extends over the wiring layer 112 except for a portion. Specifically, the barrier film 121 is provided to cover, excluding the opening H2 described above, a portion of the insulating film 111, the wiring 112X1 and the wiring 112X6 that are buried, and the wiring 112X2 and the wiring 112X5 having the opening H2 therebetween. In other words, the barrier film 121 is formed outside the opening H2 and has the end surface S121 above the wiring 112X2 and the wiring 112X5. The barrier film 121 is formed, for example, using silicon oxide (SiOₓ), silicon nitride (SiNₓ), SiCₓN_{y}, silicon carbide (SiC), silicon oxynitride (SiON, SiNO), aluminum oxynitride (AlNO), aluminum nitride (AlN), or the like.

For example, as with the barrier film 121, the insulating film 122 is intended to prevent diffusion of copper (Cu) and ingress of water in a case where the wiring 112X1 to the wiring 112X6 are formed using copper (Cu). The insulating film 122 corresponds to one specific example of a “second insulating film” of the present disclosure and is provided on the barrier film 121, and further extends to continuously cover a surface exposed in the opening H2, that is, the upper surface and the side surface of the wiring 112X2 to the wiring 112X5 as well as a bottom surface of the opening H2. As described above, the insulating film 122 is formed using an insulating material that prevents copper (Cu) diffusion and ingress of water, by using a manufacturing method with a low step coverage, for example. Specifically, for example, the insulating film 122 is formed using silicon oxide (SiOₓ), silicon nitride (SiNₓ), silicon oxynitride (SiON, SiNO), SiCₓN_{y} or the like, by using, for example, a chemical vapor deposition method (CVD method) or a coating method using a spin coater.

The insulating film 123 is provided on the insulating film 122 to generate the air gap G1, one each between the wirings in the opening H2 (specifically, between the wiring 112X2 and the wiring 112X3, between the wiring 112X3 and the wiring 112X4, and between the wiring 112V4 and the wiring 112X5). The insulating film 123 is formed using a low-k material with a low step coverage, for example, a relative permittivity (k) of 3.0 or less. Specifically, as a material for the insulating film 123, for example, it is possible to name tetraethoxysilane-based silicon oxide (TEOS SiO₂), carbon-containing silicon oxide (SiOC), SiOCH, monosilane (SiH₄) silicon oxide, porous silica, fluorine-doped silicon oxide (SiOF), inorganic SOG, organic SOG and organic polymer such as polyarylether, or the like.

The insulating film 124 is provided on the insulating film 123 to form the air gap G2 above the air gap G1 that is formed between the wirings in the opening H2 (specifically, between the wiring 112X2 and the wiring 112X3, between the wiring 112X3 and the wiring 112X4, and between the wiring 112V4 and the wiring 112X5). The insulating film 124 is formed using a low-k material having a low step coverage and having, for example, a relative permittivity (k) of 3.0 or less. Specifically, as a material for the insulating film 124, for example, it is possible to name tetraethoxysilane-based silicon oxide (TEOS SiO₂), carbon-containing silicon oxide (SiOC), SiOCH, monosilane (SiH₄) silicon oxide, porous silica, fluorine-doped silicon oxide (SiOF), inorganic SOG, organic SOG and organic polymer such as polyarylether, or the like.

The air gap G2 is formed in a self-aligned manner above the air gap G1 due to an unevenness created in the surface of the insulating film 123 when the opening H2 is closed. For example, it is possible to form the air gap G2 by forming the insulating film 124 using the same material as the insulating film 123 under a condition of a lower step coverage than a forming condition of the insulating film 123, such as by increasing a pressure during film formation.

The insulating film 125 is provided on the insulating film 124 to fill the unevenness of the insulating film 124 above the air gaps G1 and G2G and to form a planar surface above the air gaps G1 and G2G, to enable a device to be laminated using hybrid bonding such as Cu—Cu bonding. As a material for the insulating film 125, it is preferable to use a material having a higher polishing rate than the insulating films 123 and 124, for example, a relative permittivity (k) of around 4.0. As such a material, for example, it is possible to name silicon oxide (SiOₓ), carbon-containing silicon oxide (SiOC), fluorine-doped silicon oxide (SiOF) and silicon oxynitride (SiON), or the like. It is to be noted that the insulating film 125 may be a monolayer film including any type from among the above-described materials or may be formed as a laminated film including two or more types.

The insulating film 126 is provided on the insulating film 125 to be included in, for example, a bonding surface between a second substrate 20 and a third substrate 30 of the imaging element 1 described later. As a material for the insulating film 126, it is preferable to use a material having a higher polishing rate than the insulating film 123, for example, a relative permittivity (k) of about 4.0, to allow the bonding surface to be planarized. As such a material, for example, it is possible to name silicon oxide (SiOₓ), SiOC, SiOF and SiON, or the like. It is to be noted that the insulating film 126 may be a monolayer film including any one type from among the above-described materials or may be formed as a laminated film including two or more types.

The conductive layer 127 corresponds to a “first conductive film” of the present disclosure. For example, the conductive layer 127 is a wiring layer provided immediately above the wiring layer 112 including the wiring 112X1 to the wiring 112X6 that extend in one direction. For example, the conductive layer 127 is buried in the opening H3 created in a portion of the insulating film 126 and the insulating film 125, to be included in the same plane as the insulating film 126. The conductive layer 127 includes a plurality of conductive films (for example, a conductive layer 127X1 and a conductive layer 127X2), and at least a portion of the conductive layer 127 extends in one direction and is also provided to be directly opposed to at least some of the wirings 112X1 to 112X6. As an example, in FIG. 1, the conductive layer 127X1 is formed to extend, for example, in the Y-axis direction at a position directly opposed to the wiring 112X2, the wiring 112X3, and the wiring 112X4 each having the air gap G1 therebetween, as with the wiring 112X2 and the wiring 112X3. Within the opening H3, an opening H4 is created that penetrates through the barrier film 121 to the insulating film 125 to reach the wiring 112X1. The conductive layer 127X1 is also buried in this opening H4 and is electrically coupled to the wiring 112X1. It is to be noted that as the conductive layer 127X2 illustrated in FIG. 1 (not illustrated in FIG. 2), the conductive layer 127 may be formed above the wiring without the air gap G1 or G2 formed therebetween (for example, the wiring 112X6).

The conductive layer 127 includes a barrier metal 127A formed on the side surface and the bottom surface of the openings H3 and H4, and a metal film 127B that fills the openings H3 and H4. As a material for the barrier metal 127A, for example, it is possible to name Ti (titanium) or Ta (tantalum) alone, or a nitride or alloy thereof. As a material for the metal film 127B, for example, it is possible to name a metallic material that mainly includes a low-resistance metal such as Cu (copper), W (tungsten), or aluminum (Al).

It is to be noted that another layer may be provided between the insulating film 125 and the insulating film 126. For example, between the insulating film 125 and the insulating film 126, another insulating film may be provided to reduce warping due to stress that is caused when forming the conductive layer 127. For example, an insulating film like this may be formed by a CVD (Chemical vapor deposition) method, using, for example, silicon oxide (SiOₓ), silicon nitride (SiNₓ), or the like, which has a relative permittivity (k) of 7.0 or higher.

### (1-2. Method of Manufacturing Wiring Structure)

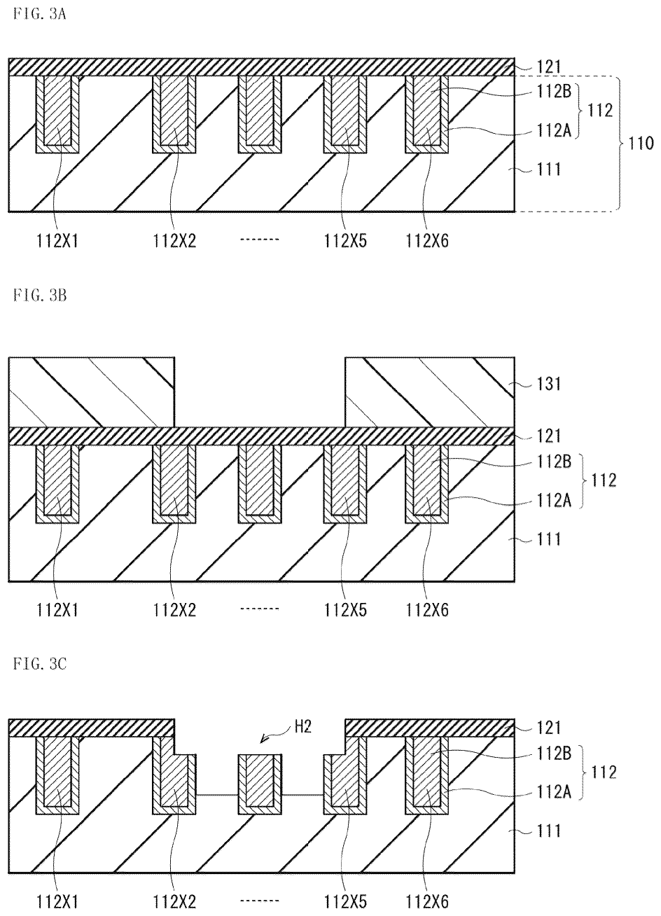

First, after the wiring layer 112 including the wiring 112X1 to the wiring 112X6 is buried in the insulating film 111, a surface is polished using a CMP (Chemical Mechanical Polishing) method, for example, to form the first layer 110. Subsequently, as illustrated in FIG. 3A, the barrier film 121 having a thickness of 10 nm to 50 nm, for example, is formed on the first layer 110, using a PVD (Physical Vapor Deposition) method or a CVD (Chemical Vapor Deposition) method, for example.

Next, as illustrated in FIG. 3B, a resist film 131 having an opening at a position corresponding to the wiring 121X2 to the wiring 112X5 is patterned on the barrier film 121, using a photolithographic technique. Subsequently, as illustrated in FIG. 3C, for example, the barrier film 121, some of the wirings from the wiring 112X2 to the wiring 112X5, and the insulating film 111 that are exposed from the resist film 131 are dry etched to create the opening H2.

Next, after the resist film 131 is removed, as illustrated in FIG. 3D, the insulating film 122 having a thickness of 5 nm to 50 nm is formed to cover a top surface of the barrier film 121 as well as a side surface and a bottom surface of the opening H2, using the CVD method, for example. Subsequently, as illustrated in FIG. 3E, the insulating film 123 including, for example, SiOC or silicon nitride and having a thickness of 10 nm to 500 nm, for example, is formed using, for example, the CVD method. This closes the opening H2, resulting in the formation of the air gap G1, one each between the wiring 112X2 and the wiring 112X3, between the wiring 112X3 and the wiring 112X4, and between the wiring 112X4 and the wiring 112V5.

Next, as illustrated in FIG. 3F, the insulating film 123 having a thickness of 100 nm to 500 nm is formed on the insulating film 123, using the CVD method, for example. At this time, the air gap G2 of minute size is formed above the air gap G1 as a result of changing a condition to a lower step coverage than when forming the insulating film 123, such as a condition using a higher pressure condition than when forming the insulating film 123.

Next, as illustrated in FIG. 3G, the insulating film 125 including, for example, SiOₓ and having a film thickness of 200 nm to 300 nm is formed on the insulating film 124, using the CVD method, for example. The insulating film 125 is then polished, for example, using a CMP method to obtain a planarized surface.

Next, the insulating film 126 is formed on the insulating film 125 using, for example, the CVD method, to have a thickness of 100 nm to 2 μm, for example. Subsequently, using a method similar to the method for the opening H2, a portion of the insulating film 126 is dry etched to create the opening H3, and then within the opening H3, the opening H4 is further created that penetrates through the barrier film 121 to the insulating film 126 to reach the wiring 112X1. Then, for example, the barrier metal 127A is formed, for example, using sputtering, on the side surface and the bottom surface of the opening H3 and the opening H4, and then the metal film 127B is formed within the opening H3 and the opening H4, for example, using plating. Finally, the barrier metal 127A and the metal film 127B that are formed on the insulating film 126 are removed by polishing, thereby forming a planar surface in which the insulating film 126 and the conductive layer 127 are included in the same plane. Thus, the wiring structure 100 illustrated in FIG. 1 is completed.

### (1-3. Configuration of Imaging Element)

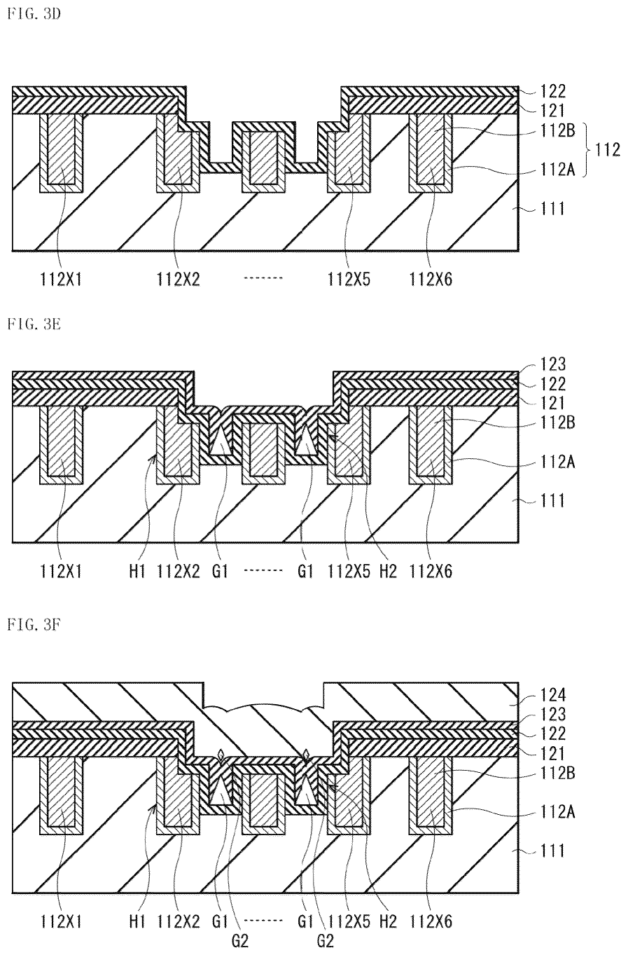

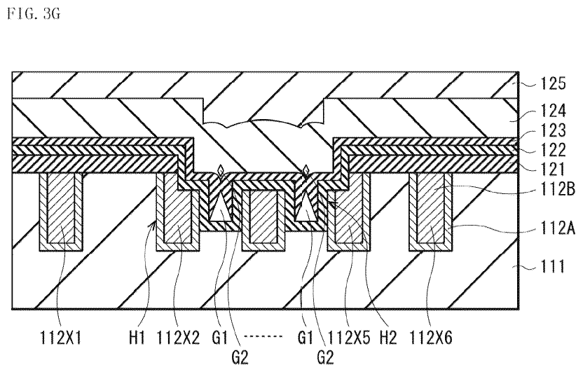

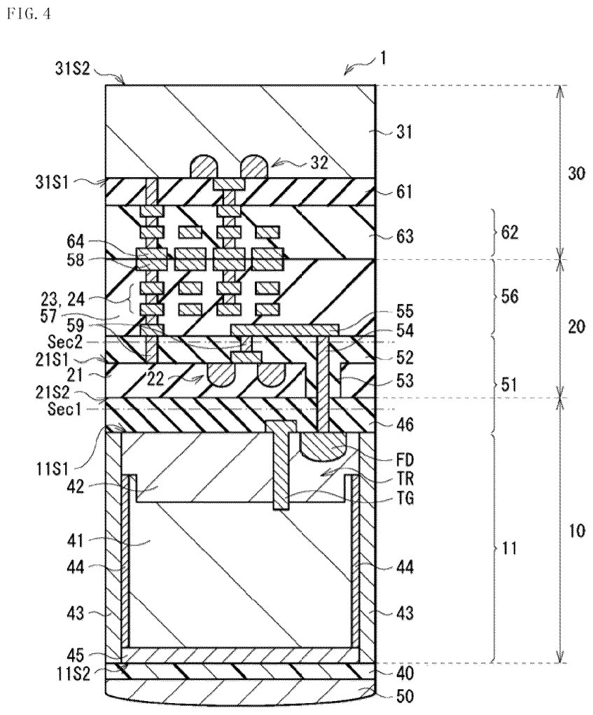

FIG. 4 illustrates an example of a vertical cross-sectional configuration of an imaging element (imaging element 1) according to one embodiment of the present disclosure. FIG. 5 illustrates one example of a schematic configuration of the imaging element 1 illustrated in FIG. 4. The imaging element 1 is an imaging element having a three-dimensional configuration in which a first substrate 10 including, on a semiconductor substrate 11, a sensor pixel 12 that performs photoelectric conversion, a second substrate 20 including, on a semiconductor substrate 21, a readout circuit 22 that outputs an image signal on the basis of an electric charge outputted from the sensor pixel 12, and a third substrate 30 including, on a semiconductor substrate 31, a logic circuit 32 that processes the pixel signal are laminated. As illustrated in FIG. 6, for example, the wiring structure 100 described above is applied to a wiring structure near a bonding surface in which the second substrate 20 is bonded to the third substrate 30.

As described above, the first substrate 10 includes, on the semiconductor substrate 11, a plurality of sensor pixels 12 that performs photoelectric conversion. The plurality of sensor pixels 12 is provided in a matrix within a pixel region 13 in the first substrate 10. The second substrate 20 includes, on the semiconductor substrate 21, the readout circuit 22 that outputs a pixel signal on the basis of the electric charge outputted from the sensor pixels 12, one for every four sensor pixels 12. The second substrate 20 includes a plurality of pixel drive lines 23 extending in a row direction and a plurality of vertical signal lines 24 extending in a column direction. The third substrate 30 includes, on the semiconductor substrate 31, the logic circuit 32 that processes the pixel signal. For example, the logic circuit 32 includes a vertical drive circuit 33, a column signal processing circuit 34, a horizontal drive circuit 35, and a system control circuit 36. The logic circuit 32 (specifically, the horizontal drive circuit 35) outputs an output voltage Vout for each sensor pixel 12 to an outside. In the logic circuit 32, for example, a low-resistance region that includes silicide such as CoSi₂ or NiSi may be formed using a salicide (Self Aligned Silicide) process, in a surface of an impurity diffusion region in contact with a source electrode and a drain electrode. In the present embodiment, the semiconductor substrate 11 corresponds to one specific example of the “first semiconductor substrate” of the present disclosure, and the first substrate 10 corresponds to one specific example of the “first substrate” of the present disclosure. The semiconductor substrate 31 corresponds to one specific example of the “second semiconductor substrate” of the present disclosure, and the third substrate 30 corresponds to one specific example of the “second substrate” of the present disclosure. It is to be noted that it is possible to consider the second substrate 20 including the semiconductor substrate 21 as being included in the “first substrate” side and the “second substrate” side of the present disclosure.

The vertical drive circuit 33, for example, sequentially selects the plurality of sensor pixels 12 on a row-by-row basis. The column signal processing circuit 34, for example, performs correlated double sampling (Correlated Double Sampling: CDS) processing on the pixel signal outputted from each sensor pixel 12 in the row selected by the vertical drive circuit 33. The column signal processing circuit 34, for example, extracts a signal level of the pixel signal by performing CDS processing and holds pixel data corresponding to an amount of light received by each sensor pixel 12. The horizontal drive circuit 35, for example, sequentially outputs the pixel data held by the column signal processing circuit 34 to the outside. The system control circuit 36, for example, controls a drive of each block (the vertical drive circuit 33, the column signal processing circuit 34, and the horizontal drive circuit 35) in the logic circuit 32.

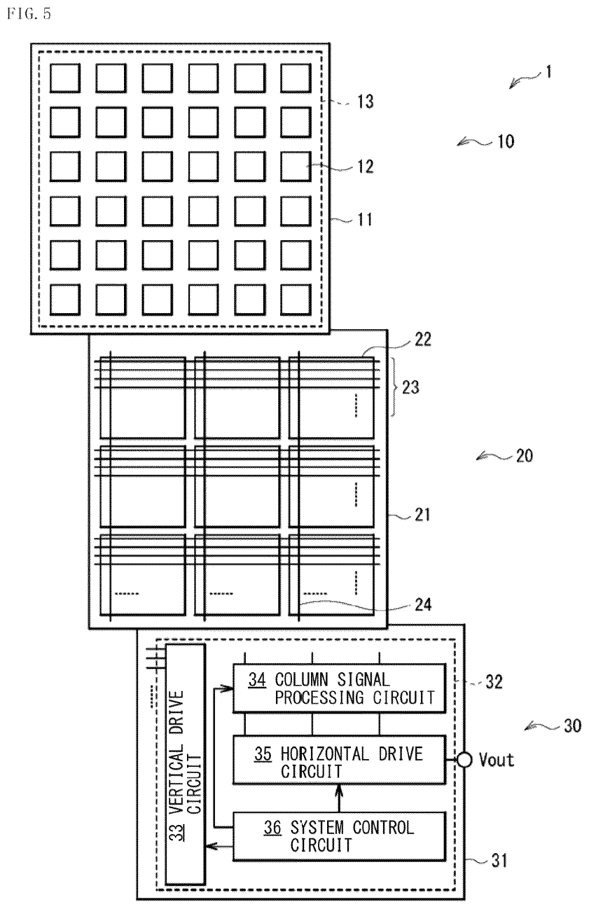

FIG. 7 illustrates one example of the sensor pixel 12 and the readout circuit 22. The following describes a case where four sensor pixels 12 share one readout circuit 22 as illustrated in FIG. 7. Here, “sharing” refers to a state in which an output from the four sensor pixels 12 is inputted to the readout circuit 22 that is shared.

Each sensor pixel 12 includes a component in common with each other. In FIG. 7, an identification number (1, 2, 3, or 4) is assigned at the end of the reference numeral for the component of each sensor pixel 12 to distinguish the component of each sensor pixel 12 from each another. In the following, in a case where it is necessary to distinguish the component of each sensor pixel 12 from each another, an identification number is assigned at the end of the reference numeral for the component of each sensor pixel 12. However, in a case where it is not necessary to distinguish the component of each sensor pixel 12 from each another, the identification number at the end of the reference numeral for the component of each sensor pixel 12 will be omitted.

For example, each sensor pixel 12 includes a photodiode PD, a transfer transistor TR electrically coupled to a photodiode PD, and a floating diffusion FD that temporarily holds the electric charge outputted from the photodiode PD via the transfer transistor TR. The photodiode PD performs photoelectric conversion to generate an electric charge corresponding to the amount of light received. The photodiode PD has a cathode electrically coupled to a source of the transfer transistor TR, and has an anode electrically coupled to a reference potential line (for example, a ground). The transfer transistor TR has a drain electrically coupled to the floating diffusion FD, and has a gate electrically coupled to a pixel drive line 23. For example, the transfer transistor TR includes a CMOS (Complementary Metal Oxide Semiconductor) transistor.

The floating diffusion FD in each sensor pixel 12 sharing one readout circuit 22 is electrically coupled to each other and is also electrically coupled to an input end of the readout circuit 22 that is shared. The readout circuit 22 includes, for example, a reset transistor RST, a selection transistor SEL, and an amplifying transistor AMP. It is to be noted that the selection transistor SEL may be omitted as necessary. The reset transistor RST has a source (an input end of the readout circuit 22) electrically coupled to the floating diffusion FD, and has a drain electrically coupled to a power line VDD and the drain of the amplifying transistor AMP. The reset transistor RST has a gate electrically coupled to the pixel drive line 23. The amplifying transistor AMP has a source electrically coupled to the drain of the selection transistor SEL, and has a gate electrically coupled to the source of the reset transistor RST. The transistor SEL has a source (an output end of the readout circuit 22) electrically coupled to the vertical signal line 24, and has a gate electrically coupled to the pixel drive line 23.

The transfer transistor TR transfers the electric charge of the photodiode PD to the floating diffusion FD when the transfer transistor TR turns on. As illustrated in FIG. 4, for example, the transfer transistor TR has a gate (transfer gate TG) extending to penetrate from the surface of the semiconductor substrate 11 through a p-well layer 42 to reach a depth as far as a PD 41. The reset transistor RST resets a potential of the floating diffusion FD to a predetermined potential. When turned on, the reset transistor RST resets the potential of the floating diffusion FD to a potential of the power supply line VDD. The selection transistor SEL controls an output timing of the pixel signal from the readout circuit 22. The amplifying transistor AMP generates, as a pixel signal, a signal of a voltage corresponding to a level of the electric charge held in the floating diffusion FD. The amplifying transistor AMP is included in a source-follower type amplifier and outputs a pixel signal of a voltage corresponding to a level of the electric charge generated at the photodiode PD. When the selection transistor SEL turns on, the amplifying transistor AMP amplifies the potential of the floating diffusion FD and outputs a voltage corresponding to the potential to the column signal processing circuit 34 via the vertical signal line 24. The reset transistor RST, the amplifying transistor AMP, and the selection transistor SEL are CMOS transistors, for example.

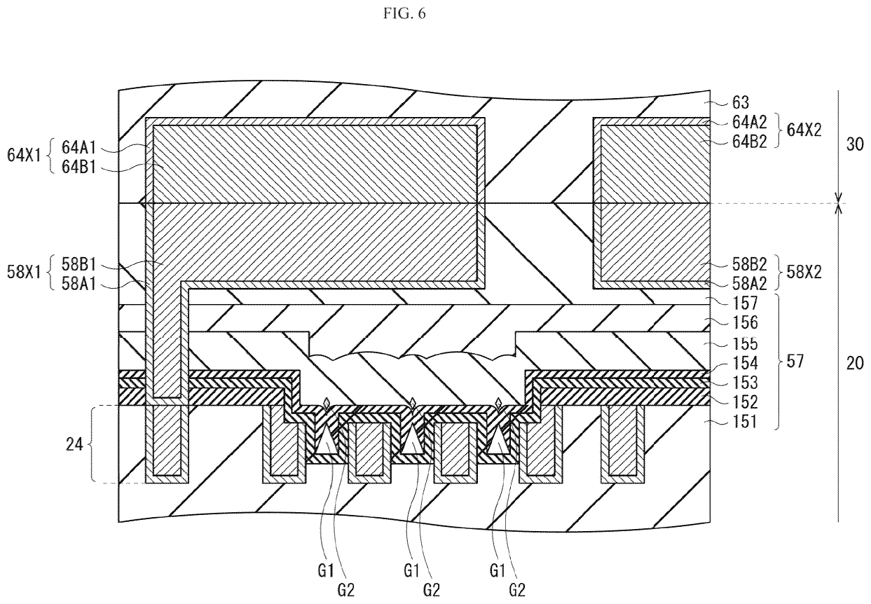

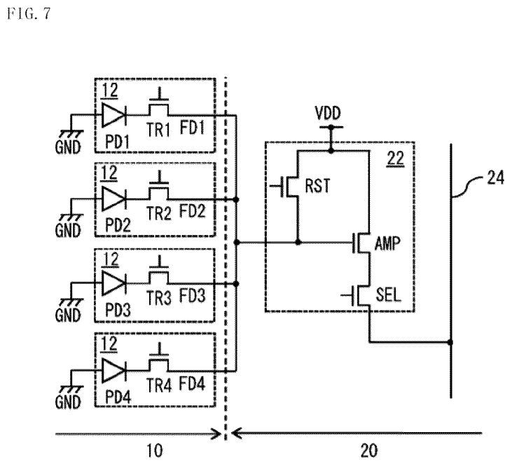

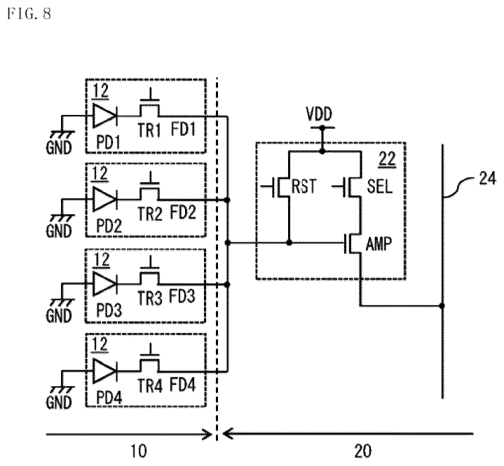

It is to be noted that as illustrated in FIG. 8, the selection transistor SEL may be provided between the power line VDD and the amplifying transistor AMP. In this case, the reset transistor RST has a drain electrically coupled to the power line VDD and the drain of the selection transistor SEL. The selection transistor SEL has a source electrically coupled to the drain of the amplifying transistor AMP, and has a gate electrically coupled to the pixel drive line 23. The amplifying transistor AMP has a source (an output end of the readout circuit 22) electrically coupled to the vertical signal line 24, and has a gate electrically coupled to the source of the reset transistor RST. In addition, as illustrated in FIGS. 9 and 10, the FD transfer transistor FDG may be provided between the source of the reset transistor RST and the gate of the amplifying transistor AMP.

The FD transfer transistor FDG is used when switching a conversion efficiency. In general, the pixel signal is small when an image is captured in a dark place. When performing charge-voltage conversion on the basis of Q=CV, if the capacitance of the floating diffusion FD (FD capacitance C) is large, V becomes small when converted to a voltage by the amplifying transistor AMP. On the other hand, because the pixel signal becomes larger in a bright location, it is difficult to allow the floating diffusion FD to sufficiently receive the electric charge of the photodiode PD unless the FD capacitance C is large. Furthermore, it is necessary that the FD capacitance C is large enough to prevent V from becoming too large (in other words, to cause V to become small) when converted to a voltage by the amplifying transistor AMP. Considering these points, when the FD transfer transistor FDG is turned on, the gate capacitance of the FD transfer transistor FDG increases, resulting in a larger total FD capacitance C. In contrast, when the FD transfer transistor FDG is turned off, the total FD capacitance C becomes smaller. Thus, it is possible to vary the FD capacitance C by switching the FD transfer transistor FDG on and off, thereby switching the conversion efficiency.

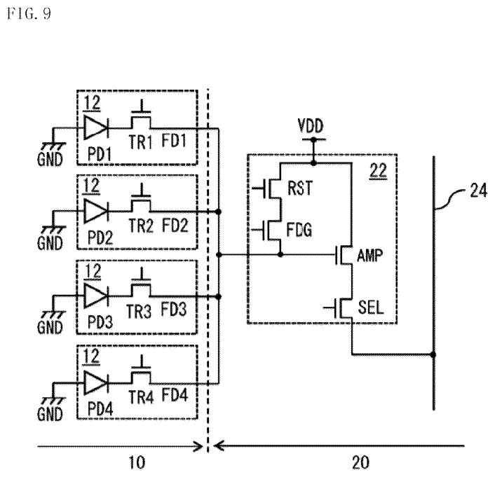

FIG. 11 illustrates an example of a coupling mode between a plurality of readout circuits 22 and a plurality of vertical signal lines 24. In a case where the plurality of readout circuits 22 is arranged side by side in a direction of extension of the vertical signal lines 24 (for example, a column direction), the plurality of vertical signal lines 24 may be assigned one for each readout circuit 22. For example, as illustrated in FIG. 11, in a case where four readout circuits 22 are arranged side by side in the direction of extension of the vertical signal lines 24 (for example, a column direction), four vertical signal lines 24 may be assigned one for each readout circuit 22. It is to be noted that in FIG. 11, an identification number (1, 2, 3, or 4) is assigned at an end of the reference numeral for each vertical signal line 24 to distinguish each vertical signal line 24.

Next, a vertical cross-sectional configuration of the imaging element 1 will be described with reference to FIG. 4. As described above, the imaging element 1 has a configuration in which the first substrate 10, the second substrate 20, and the third substrate 30 are laminated in this order. The imaging element 1 also includes a color filter 40 and a light-receiving lens 50 on a back surface (light-entering surface) side of the first substrate 10. For example, the color filter 40 and the light-receiving lens 50 are each provided one for each sensor pixel 12. In other words, the imaging element 1 is a back-illuminated type imaging element.

The first substrate 10 includes an insulating layer 46 that is laminated on a surface (surface 11S1) of the semiconductor substrate 11. The first substrate 10 includes the insulating layer 46 as a portion of an interlayer insulating film 51. The insulating layer 46 is provided between the semiconductor substrate 11 and the semiconductor substrate 21 described later. The semiconductor substrate 11 includes a silicon substrate. For example, the semiconductor substrate 11 includes the p-well layer 42 in a portion of the surface and an adjacent region thereof, and includes the PD 41 having a conductivity type different from that of the p-well layer 42 in another region (a region deeper than the p-well layer 42). The p-well layer 42 includes a p-type semiconductor region. The PD 41 includes a semiconductor region having a conductivity type (specifically, n-type) different from that of the p-well layer 42. The semiconductor substrate 11 has a floating diffusion FD within the p-well layer 42 as a semiconductor region having a conductivity type (specifically, n-type) different from that of the p-well layer 42.

The first substrate 10 includes a photodiode PD, a transfer transistor TR, and a floating diffusion FD for each sensor pixel 12. The first substrate 10 has a configuration in which the transfer transistor TR and the floating diffusion FD are provided on a portion of the surface 11S1 side (on an opposite side of the light-entering surface side, that is, on the second substrate 20 side) of the semiconductor substrate 11. The first substrate 10 has an element separation section 43 that separates each sensor pixel 12. The element separation section 43 is formed to extend in a normal direction of the semiconductor substrate 11 (a direction perpendicular to the surface of the semiconductor substrate 11). The element separation section 43 is provided between two sensor pixels 12 adjacent to each other. The element separation section 43 electrically separates the sensor pixels 12 adjacent to each other. For example, the element separation section 43 includes silicon oxide. For example, the element separation section 43 penetrates through the semiconductor substrate 11. The first substrate 10, for example, further includes a p-well layer 44 in contact with a surface that is a side surface of the element separation section 43 and is also on the photodiode PD side. The p-well layer 44 includes a semiconductor region of a different conductivity type (specifically, p-type) from the photodiode PD. Furthermore, for example, the first substrate 10 has a fixed charge film 45 in contact with a back surface (a surface 11S2 or another surface) of the semiconductor substrate 11. The fixed charge film 45 is negatively charged to suppress generation of a dark current caused by an interface state on a light-receiving surface side of the semiconductor substrate 11. For example, the fixed charge film 45 includes an insulating film having a negative fixed charge. As a material for such an insulating film, for example, it is possible to name hafnium oxide, zircon oxide, aluminum oxide, titanium oxide, or tantalum oxide. The electric field induced by the fixed charge film 45 results in the formation of a hole accumulation layer at an interface on the light-receiving surface side of the semiconductor substrate 11. This hole accumulation layer suppresses generation of electrons from the interface. The color filter 40 is provided on the back surface side of the semiconductor substrate 11. For example, the color filter 40 is provided in contact with the fixed charge film 45 and is provided at a position opposed to the sensor pixel 12 via the fixed charge film 45. For example, the light-receiving lens 50 is provided in contact with the color filter 40 and is provided at a position opposed to the sensor pixel 12 via the color filter 40 and the fixed charge film 45.

The second substrate 20 includes an insulating layer 52 that is laminated on the semiconductor substrate 21. The second substrate 20 includes the insulating layer 52 as a portion of the interlayer insulating film 51. The insulating layer 52 is provided between the semiconductor substrate 21 and the semiconductor substrate 31. The semiconductor substrate 21 includes a silicon substrate. The second substrate 20 has the readout circuit 22 one for every four sensor pixels 12. The second substrate 20 has a configuration in which the readout circuit 22 is provided on a portion of the surface (a surface 21S1 opposed to the third substrate 30 or one surface) side of the semiconductor substrate 21. The second substrate 20 is bonded to the first substrate 10, with aback surface (surface 21S2) of the semiconductor substrate 21 oriented toward the surface (surface 11S1) of the semiconductor substrate 11. In other words, the second substrate 20 is bonded to the first substrate 10 in a face-to-back manner. Furthermore, the second substrate 20 includes, within the same layer as the semiconductor substrate 21, an insulating layer 53 that penetrates through the semiconductor substrate 21. The second substrate 20 includes the insulating layer 53 as a portion of the interlayer insulating film 51. The insulating layer 53 is provided to cover a side surface of a through wiring 54 described later.

A laminated body including the first substrate 10 and the second substrate 20 includes the interlayer insulating film 51 and the through wiring 54 provided in the interlayer insulating film 51. The laminated body described above includes the through wiring 54 one for each sensor pixel 12. The through wiring 54 extends in a normal direction of the semiconductor substrate 21 and is provided to penetrate through a point in the interlayer insulating film 51, which includes the insulating layer 53. The first substrate 10 and the second substrate 20 are electrically coupled to each other by the through wiring 54. Specifically, the through wiring 54 is electrically coupled to the floating diffusion FD and the coupling wiring 55 described later.

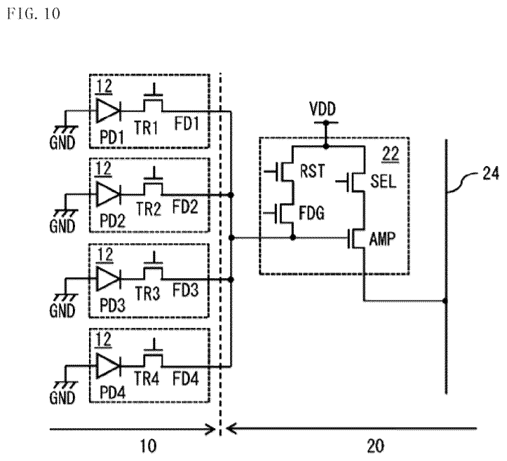

The laminated body including the first substrate 10 and the second substrate 20 further includes through wirings 47 and 48 (see FIG. 12 described later) provided in the interlayer insulating film 51. The laminated body described above includes one through wiring 47 and one through wiring 48 for each sensor pixel 12. The through wirings 47 and 48 each extend in the normal direction of the semiconductor substrate 21 and are provided to penetrate through a point in the interlayer insulating film 51, which includes the insulating layer 53. The first substrate 10 and the second substrate 20 are electrically coupled to each other by the through wirings 47 and 48. Specifically, the through wiring 47 is electrically coupled to the p-well layer 42 of the semiconductor substrate 11 and the wiring in the second substrate 20. The through wiring 48 is electrically coupled to the transfer gate TG and the pixel drive lines 23.

For example, the second substrate 20 includes, in the insulating layer 52, a plurality of coupling sections 59 electrically coupled to the readout circuit 22 and the semiconductor substrate 21. Furthermore, for example, the second substrate 20 has a wiring layer 56 on the insulating layer 52. The wiring layer 56 includes, for example, an insulating layer 57, and a plurality of pixel drive lines 23 and a plurality of vertical signal lines 24 that are provided in the insulating layer 57. Furthermore, for example, the wiring layer 56 includes a plurality of coupling wirings 55 within the insulating layer 57, one for every four sensor pixels 12. The coupling wiring 55 electrically couples, to each other, the respective wirings 54 electrically coupled to the floating diffusion FD included in the four sensor pixels 12 sharing the readout circuit 22. Here, the total number of the through wirings 54 and 48 is larger than the total number of the sensor pixels 12 included in the first substrate 10, and is two times the total number of the sensor pixels 12 included in the first substrate 10. In addition, the total number of the through wirings 54, 48, and 47 is larger than the total number of the sensor pixels 12 included in the first substrate 10, and is three times the total number of the sensor pixels 12 included in the first substrate 10.

Furthermore, for example, the wiring layer 56 includes a plurality of pad electrodes 58 in the insulating layer 57. Each pad electrode 58 includes, for example, a metal such as Cu (copper), tungsten (W), or Al (aluminum). Each pad electrode 58 is exposed on a surface of the wiring layer 56. Each pad electrode 58 is used for electrical coupling between the second substrate 20 and the third substrate 30 as well as for bonding the second substrate 20 and the third substrate 30. The plurality of pad electrodes 58 is provided, for example, one for each pixel drive line 23 and vertical signal line 24. Here, for example, the total number of the pad electrodes 58 (or the total number of bonding between the pad electrodes 58 and the pad electrodes 64 (described later)) is smaller than the total number of the sensor pixels 12 included in the first substrate 10.

FIG. 6 schematically illustrates a cross-sectional configuration when the wiring structure 100 described above is applied to the imaging element 1. In the present embodiment, for example, the plurality of vertical signal lines 24 corresponds to the wiring 112X3 and the wiring 112X4 in the wiring structure 100 described above, and the power line VSS corresponds to the wiring 112X2 and the wiring 112X5 in the above-described wiring structure 100. Although not illustrated in FIG. 4, the insulating layer 57 includes a plurality of insulating films 151 to 157 including a barrier film 152 as illustrated in FIG. 6. Of these films, the insulating film 154 forms the air gaps G1 and G2, one each between the power supply line VSS and the vertical signal line 24 extending parallel to each other, between each of the plurality of vertical signal lines 24, and above the vertical signal lines 24. The pad electrodes 58 (pad electrodes 58X1 and 58X2) exposed on the surface of the wiring layer 56 correspond respectively to the conductive layer 127X1 and the conductive layer 127X2 in the wiring structure 100 described above.

A portion of each pad electrode 58 (a pad electrode 58X1) is electrically coupled to a ground line (the wiring 112X1). For example, although not illustrated, the ground line is coupled to a p-well or a ground (GND) of the semiconductor substrate 11. This makes it possible to use the pad electrode 58X1 as a shield wiring for the vertical signal line 24 in a lamination direction, thus suppressing noise generation in the vertical signal line 24.

Furthermore, the pad electrode 58X1 that functions as the shield wiring is bonded to the pad electrode 64X1 on the third substrate 30 side described later. This makes it possible to lower an impedance of the shield wiring compared to a case of forming the shield wiring with the pad electrode 58X1 alone. In addition, for example, as with the vertical signal line 24, the pad electrode 58X1 that functions as the shield wiring is provided to extend vertically across the pixel region 13 to be terminated near a periphery beyond a regional edge of the pixel region 13.

For example, the third substrate 30 includes an interlayer insulating film 61 that is laminated on the semiconductor substrate 31. It is to be noted that as described later, because the third substrate 30 is bonded to the second substrate 20 on the surface side in a face-to-face manner, the vertical direction in the description is reversed from the vertical direction in the drawing when describing the configuration in the third substrate 30. The semiconductor substrate 31 includes a silicon substrate. The third substrate 30 has a configuration in which a logic circuit 32 is provided on a portion of a surface (surface 31S1) side of the semiconductor substrate 31. Furthermore, for example, the third substrate 30 has a wiring layer 62 on the interlayer insulating film 61. The wiring layer 62 includes, for example, an insulating layer 63 and a plurality of pad electrodes 64 (for example, a pad electrode 64X1 and a pad electrode 64X2) provided in the insulating layer 63. The plurality of pad electrodes 64 is electrically coupled to the logic circuit 32. Each pad electrode 64 includes copper (Cu), for example. Each pad electrode 64 is exposed on the surface of the wiring layer 62. Each pad electrode 64 is used for electrical coupling between the second substrate 20 and the third substrate 30 as well as for bonding the second substrate 20 and the third substrate 30. In addition, it is not always necessary to provide a plurality of pad electrodes 64, but it is also possible to provide only one pad electrode 64 to electrically couple to the logic circuit 32. The second substrate 20 and the third substrate 30 are electrically coupled to each other through the coupling between the pad electrodes 58 and 64. In other words, the transfer transistor TR has a gate (transfer gate TG) electrically coupled to the logic circuit 32 via the through wiring 54 and the pad electrodes 58 and 64. The third substrate 30 is bonded to the second substrate 20, with the surface (surface 31S1) of the semiconductor substrate 31 oriented toward the surface (surface 21S1) side of the semiconductor substrate 21. In other words, the third substrate 30 is bonded to the second substrate 20 in a face-to-face manner.

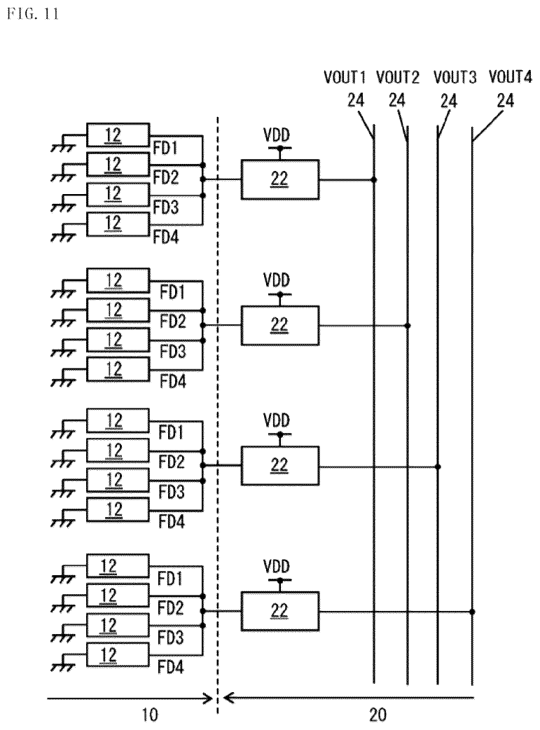

FIGS. 12 and 13 each illustrate an example of a horizontal cross-sectional configuration of the imaging element 1. An upper view in each of FIGS. 12 and 13 illustrates an example of the cross-sectional configuration at a cross section Sec1 in FIG. 4, and a lower view in each of FIGS. 12 and 13 illustrates an example of the cross-sectional configuration at a cross section Sec2 in FIG. 4. FIG. 12 illustrates an example of a configuration in which two sets of four 2×2 sensor pixels 12 are arranged in a second direction H, and FIG. 13 illustrates an example of a configuration in which four sets of four 2×2 sensor pixels 12 are arranged in a first direction V and the second direction H. It is to be noted that in the upper cross-sectional view in FIGS. 12 and 13, a view illustrating an example of a surface configuration of the semiconductor substrate 11 is superimposed on the view illustrating an example of the cross-sectional configuration at the cross section Sec1 in FIG. 4, and the insulating layer 46 is omitted. In addition, in the lower cross-sectional view in FIGS. 12 and 13, a view illustrating an example of a surface configuration of the semiconductor substrate 21 is superimposed on the view illustrating an example of the cross-sectional configuration at the cross section Sec2 in FIG. 4.

As illustrated in FIGS. 12 and 13, the plurality of through wirings 54, the plurality of through wirings 48, and the plurality of through wirings 47 are arranged in a belt-like shape in the first direction V (a vertical direction in FIG. 12 and a horizontal direction in FIG. 13) in a plane of the first substrate 10. It is to be noted that FIGS. 12 and 13 illustrate an example of a case where the plurality of through wirings 54, the plurality of through wirings 48, and the plurality of through wirings 47 are arranged in two columns in the first direction V. The first direction V is parallel to one array direction (for example, a column direction) of two array directions (for example, (for example, a row direction and a column direction) of the plurality of sensor pixels 12 arranged in a matrix. In the four sensor pixels 12 sharing the readout circuit 22, for example, the four floating diffusions FD are arranged adjacent to each other via the element separation section 43. In the four sensor pixels 12 sharing the readout circuit 22, the four transfer gates TG are arranged to surround the four floating diffusions FD, for example, in a ring shape by the four transfer gates TG.

The insulating layer 53 includes a plurality of blocks extending in the first direction V. The semiconductor substrate 21 includes a plurality of blocks 21A having an island shape, and the plurality of blocks 21A extends in the first direction V while being arranged side by side in the second direction H orthogonal to the first direction V via the insulating layer 53. For example, each block 21A includes a plurality of sets of reset transistors RST, amplifying transistors AMP, and selection transistors SEL. One readout circuit 22 shared by the four sensor pixels 12 includes, for example, the reset transistors RST, the amplifying transistors AMP, and the selection transistors SEL that are provided in a region opposed to the four sensor pixels 12. For example, one readout circuit 22 shared by the four sensor pixels 12 includes the amplifying transistor AMP in a block 21A adjacent to the insulating layer 53 on the left, and includes the reset transistor RST and the selection transistor SEL in a block 21A adjacent to the insulating layer 53 on the right.

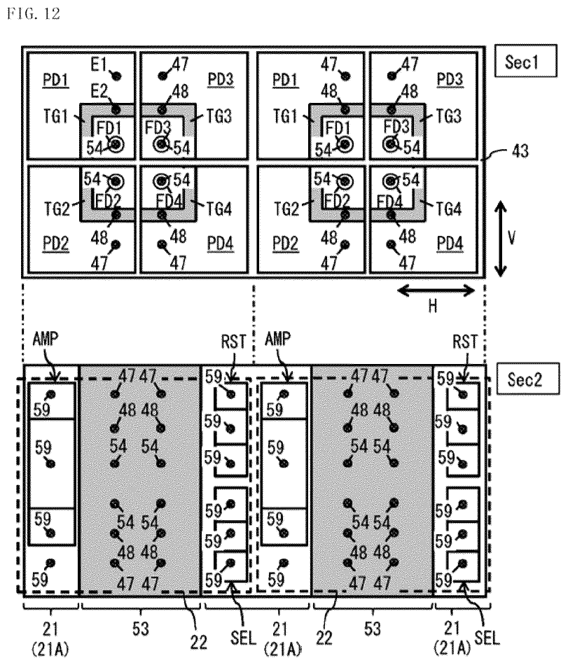

FIGS. 14, 15, 16, and 17 each illustrate one example of a wiring layout in a horizontal plane of the imaging element 1. FIGS. 14 to 17 illustrate an example of a case where one readout circuit 22 shared by four sensor pixels 12 is provided in the region opposed to the four sensor pixels 12. For example, the wirings described in FIGS. 14 to 17 are provided within layers different from each other in the wiring layer 56.

As illustrated in FIG. 14, for example, the four through wirings 54 adjacent to each other are electrically coupled to the coupling wiring 55. Furthermore, as illustrated in FIG. 14, for example, the four through wirings 54 adjacent to each other are electrically coupled to, via the coupling wiring 55 and the coupling section 59, the gate of the amplifying transistor AMP included in the block 21A adjacent to the insulating layer 53 on the left and the gate of the reset transistor RST included in the block 21A adjacent to the insulating layer 53 on the right.

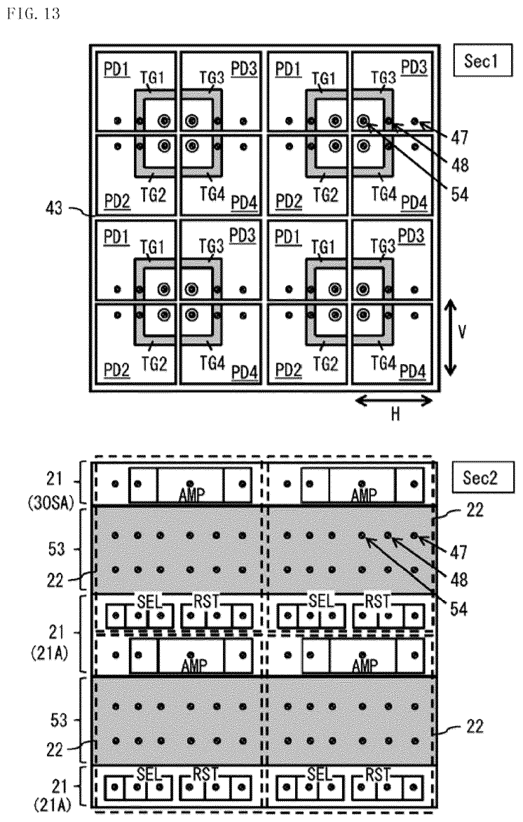

As illustrated in FIG. 15, for example, the power supply line VDD is provided at a position opposed to each readout circuits 22 arranged side by side in the second direction H. As illustrated in FIG. 15, for example, the power supply line VDD is electrically coupled to, via the coupling section 59, the drain of the amplifier transistor AMP and the drain of the reset transistor RST in each readout circuit 22 arranged side by side in the second direction H. As illustrated in FIG. 15, for example, two pixel drive lines 23 are provided at a position opposed to each readout circuit 22 arranged side by side in the second direction H. As illustrated in FIG. 15, for example, one pixel drive line 23 (a second control line) is a wiring RSTG that is electrically coupled to the gate of the reset transistor RST in each readout circuit 22 arranged side by side in the second direction H. As illustrated in FIG. 15, for example, another pixel drive line 23 (a third control line) is a wiring SELG that is electrically coupled to the gate of the selection transistor SEL in each readout circuit 22 arranged side by side in the second direction H. As illustrated in FIG. 15, for example, in each readout circuit 22, the source of the amplifier transistor AMP and the drain of the selection transistor SEL are electrically coupled to each other via the wiring 25.

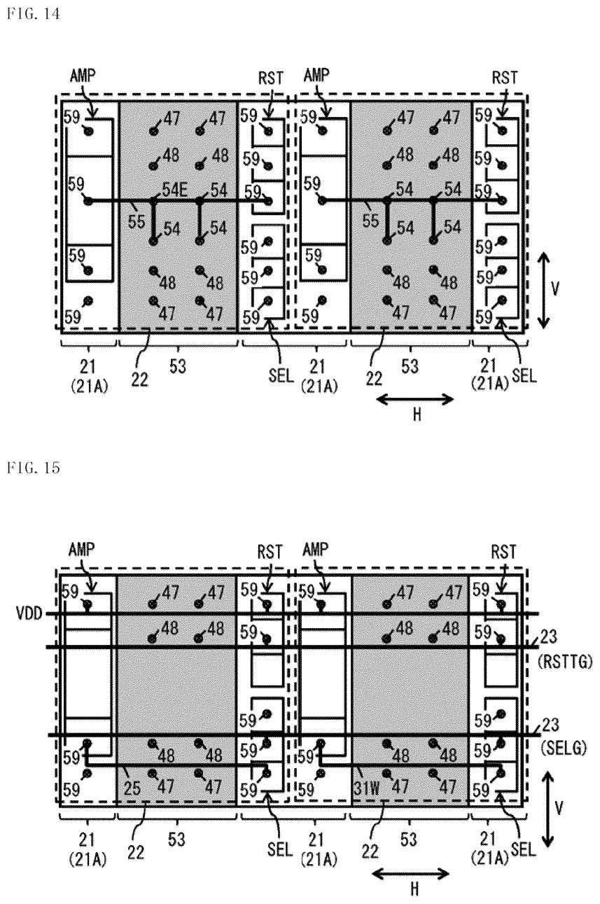

For example, as illustrated in FIG. 16, two power supply lines VSS are arranged at a position opposed to each readout circuit 22 arranged side by side in the second direction H. As illustrated in FIG. 16, for example, each power supply line VSS is electrically coupled to a plurality of through wirings 47 at a position opposed to each sensor pixel 12 arranged side by side in the second direction H. The four pixel drive lines 23, as illustrated in FIG. 16, for example, are arranged at a position opposed to each readout circuit 22 arranged side by side in the second direction H. As illustrated in FIG. 16, for example, the four pixel drive lines 23 are each a wiring TRG that is electrically coupled to the through wiring 48 of one of the four sensor pixels 12 corresponding to each readout circuit 22 arranged side by side in the second direction H. In other words, the four pixel drive lines 23 (first control lines) are electrically coupled to the gate (transfer gate TG) of the transfer transistor TR of each sensor pixel 12 arranged side by side in the second direction H. In FIG. 16, an identifier (1, 2, 3, or 4) is assigned at an end of each wiring TRG to distinguish each wiring TRG.

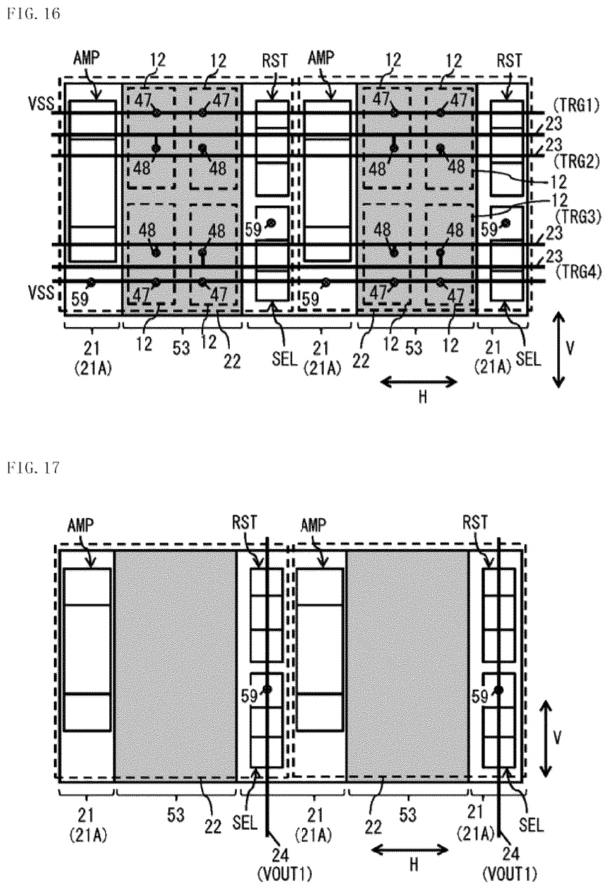

As illustrated in FIG. 17, for example, the vertical signal line 24 is provided at a position opposed to each readout circuit 22 arranged side by side in the first direction V. As illustrated in FIG. 17, for example, the vertical signal line 24 (output line) is electrically coupled to the output end (the source of the amplifying transistor AMP) of each readout circuit 22 arranged side by side in the first direction V.

### (1-4. Method of Manufacturing Imaging Element)

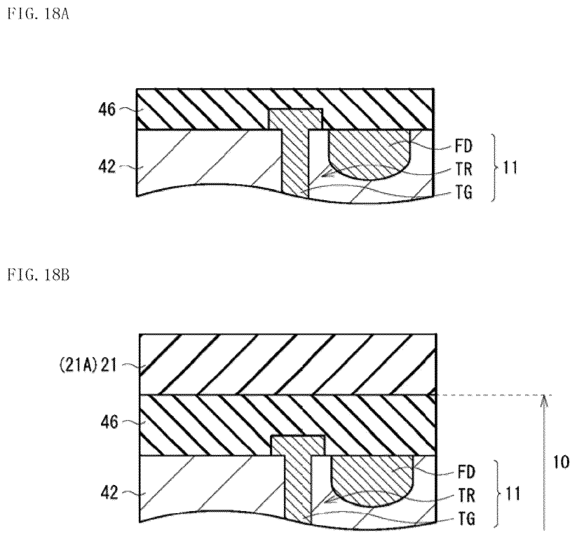

Next, a method of manufacturing the imaging element 1 will be described. FIGS. 18A to 18G each illustrate one example of a manufacturing process for the imaging element 1.

First, the p-well layer 42, the element separation section 43, and the p-well layer 44 are formed on the semiconductor substrate 11. Next, the photodiode PD, the transfer transistor TR, and the floating diffusion FD are formed on the semiconductor substrate 11 (FIG. 18A). This results in the formation of the sensor pixel 12 on the semiconductor substrate 11. At this time, as an electrode material used in the sensor pixel 12, it is preferable not to use a low heat-resistant material such as CoSi₂ or NiSi by salicide process. As the electrode material used in the sensor pixel 12, it is rather preferable to use a material having a high heat resistance. As an example of the material having a high heat resistance, it is possible to name polysilicon. Then, the insulating layer 46 is formed on the semiconductor substrate 11 (FIG. 18A). In this manner, the first substrate 10 is formed.

Next, the semiconductor substrate 21 is bonded onto the first substrate 10 (insulating layer 46B) (FIG. 18B). Then, the semiconductor substrate 21 is thinned as necessary. At this time, the semiconductor substrate 21 is formed to have a thickness necessary for forming the readout circuit 22. In general, the semiconductor substrate 21 has a thickness of a few hundred nm. However, depending on a concept of the readout circuit 22, an FD (Fully Depleted) type is also possible, in which case, it is possible to adopt a range of several nm to several m for the thickness of the semiconductor substrate 21.

Subsequently, the insulating layer 53 is formed in the same layer as the semiconductor substrate 21 (FIG. 18C). The insulating layer 53 is formed, for example, at a point opposed to the floating diffusion FD. For example, a slit (opening 21H) penetrating through the semiconductor substrate 21 is created to separate the semiconductor substrate 21 into a plurality of blocks 21A. Then, the insulating layer 53 is formed to fill the slit. Then, the readout circuit 22 including the amplifying transistor AMP or the like is formed in each block 21A of the semiconductor substrate 21 (FIG. 18C). At this time, in a case where a metallic material having a high heat resistance is used as the electrode material for the sensor pixel 12, it is possible to form the gate insulating film of the readout circuit 22 by thermal oxidation.

Next, the insulating layer 52 is formed on the semiconductor substrate 21. In this manner, the interlayer insulating film 51 including the insulating layers 46, 52, and 53 is formed. Subsequently, through holes 51A and 51B are formed in the interlayer insulating film 51 (FIG. 18D). Specifically, in the insulating layer 52, the through hole 51B penetrating through the insulating layer 52 is formed at a point opposed to the readout circuit 22. In addition, in the interlayer insulating film 51, the through hole 51A penetrating through the interlayer insulating film 51 is formed at a point opposed to the floating diffusion FD (in other words, at a point opposed to the insulating layer 53).

Subsequently, by burying a conductive material in the through holes 51A and 51B, the through wiring 54 is formed in the through hole 51A, while the coupling section 59 is formed in the through hole 51B (FIG. 18E). Furthermore, on the insulating layer 52, the coupling wiring 55 is formed to electrically couple the through wiring 54 and the coupling section 59 to each other (FIG. 18E). Then, the wiring layer 56 is formed on the insulating layer 52 (FIG. 18F). In this manner, the second substrate 20 is formed.

Next, the second substrate 20 is bonded to the third substrate 30 including the logic circuit 32 and the wiring layer 62, with a surface of the semiconductor substrate 21 oriented toward a surface side of the semiconductor substrate 31 (FIG. 18G). At this time, the pad electrode 58 of the second substrate 20 and the pad electrode 64 of the third substrate 30 are joined together to electrically couple the second substrate 20 and the third substrate 30 to each other. In this manner, the imaging element 1 is manufactured.

### (1-5. Workings and Effects)

The wiring structure 100 of the present embodiment and the imaging element 1 to which the present embodiment is applied has the air gap G1 between a plurality of wirings extending in one direction (for example, in the Y-axis direction), and further has the air gap G2 thereabove. For example, for the wiring 112X1 to the wiring 12X6 extending in the Y-axis direction and buried by the insulating film 123, the air gap G1 is formed, one each between adjacent wirings, that is, between adjacent wirings 112X2 and 112X3, between the wirings 112X3 and 112X4, and between the wirings 112X4 and 112X5, and the G2 is formed thereabove. This reduces the capacitance between the wirings extending in one direction. In the following, this will be described.

As described earlier, in recent years, along with the miniaturization of a semiconductor integrated circuit element, a wiring that couples between and within each element has become smaller in spacing, and interwiring capacitance (parasitic capacitance) has tended to increase. An increase in interwiring capacitance delays a wiring signal, and this has a disadvantage of reducing the operating speed of a device. For this reason, in a general semiconductor device, a reduction of the interwiring parasitic capacitance is sought by electrically insulating between the wirings in the lamination direction using a low-k material and by forming an air gap between parallel wirings.

In the semiconductor device as described above, in a case where a via for coupling to an upper layer is formed for each wiring with an air gap therebetween, there is a restriction that the air gap is not formed adjacent to the wiring with which the via is formed. For this reason, it is difficult to sufficiently reduce the capacitance of the wiring layer as a whole.

In addition, for example, in a case where the wiring is formed using copper (Cu), in general, the barrier film having a high value of relative permittivity (k) is laminated on the Cu wiring. For this reason, there is a disadvantage in that a wiring portion without an air gap is caused to have a higher capacitance in the lamination direction.

Whereas, in the present embodiment, for example, a portion of the wirings from the wiring 112X2 to the wiring 112X5 and the insulating film 111 are dry etched, for example, to create the opening H2. The insulating film 123 is then formed, for example, using the CVD method, to form the air gap G1, one each between the wiring 112X2 and the wiring 112X3, between the wiring 112X3 and the wiring 112X4, and between the wiring 112X4 and the wiring 112V5. Then, the insulating film 124 is formed under a condition of a lower step coverage than a forming condition of the insulating film 123, thereby forming the air gap G2 above the air gap G1. This reduces the capacitance between and near the wirings.

Thus, the wiring structure 100 of the present embodiment makes it possible to reduce the wiring capacitance of an entire structure. In addition, for example, for the imaging element 1 to which the wiring structure 100 of the present embodiment is applied, it is possible to reduce the wiring capacitance between and near the wirings for the plurality of vertical signal lines 24 extending vertically across the pixel region 13.

In the following, the second and the third embodiments and modification examples 1 to 11 will be described. It is to be noted that in the following description, components similar to those in the above embodiment will be denoted by the same reference numerals and the description thereof will be omitted as appropriate.

### Second Embodiment

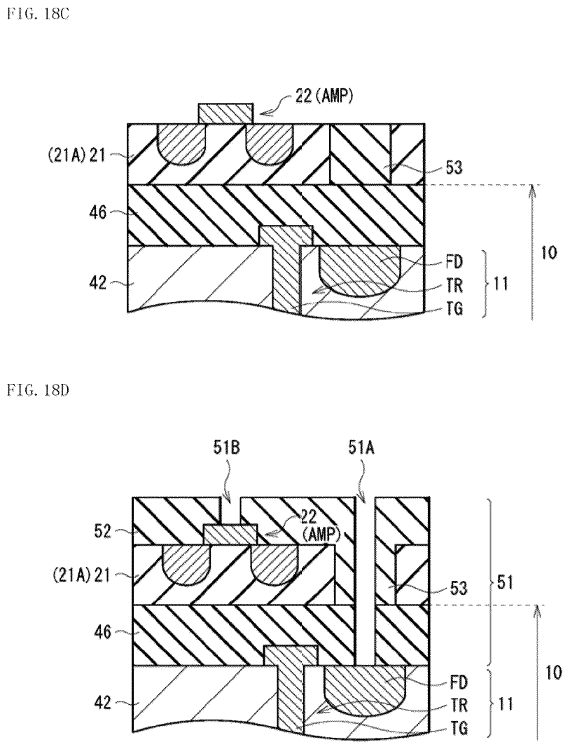

FIG. 19 schematically illustrates an example of a vertical cross-sectional configuration of a wiring structure (wiring structure 100A) according to a second embodiment of the present disclosure. For example, as in the second embodiment described above, the wiring structure 100A has a multilayer wiring configuration in which a plurality of wiring layers are laminated, and is applicable to, for example, the imaging element 1 described later.

The wiring structure 100A includes a wiring layer 112 including a plurality of wirings (for example, the wiring 112X1 to the wiring 112X6) extending in one direction (for example, in a Y-axis direction). The wiring structure 100A includes a barrier film 121 and insulating films 123 and 128, which are laminated on the wiring layer 112 in order. For example, the barrier film 121 extends over the wiring layer 112, and, for example, has an end surface S121 on each of a wiring 112X2 and a wiring 112X5. The insulating film 123 is laminated above the barrier film 121 and is also provided to fill an opening H2 between each adjacent wiring (for example, between the wiring 112X2 and the wiring 112X3, between the wiring 112X3 and the wiring 112X4, and between the wiring 112X4 and the wiring 112X5). The insulating film 128 is laminated on the insulating film 123.

In the present embodiment, the insulating film 128 corresponds to one specific example of a “third insulating film” of the present disclosure, and has an air gap G1, one each between adjacent wirings, that is, between the wiring 112X2 and the wiring 112X3, between the wiring 112X3 and the wiring 112X4, and between the wiring 112X4 and the wiring 112X5, and further has, above the air gap G1, an air gap G2 having a smaller volume than the air gap G1.

The insulating film 128 is provided on the insulating film 123 to form an air gap G2 above the air gap G1 that is formed between the wirings in the opening H2 (specifically, between the wiring 112X2 and the wiring 112X3, between the wiring 112X3 and the wiring 112X4, and between the wiring 112V4 and the wiring 112X5). The air gap G2 is formed in a self-aligned manner above the air gap G1 due to an unevenness created in the surface of the insulating film 123 when the opening H2 is closed. For the insulating film 128, a material having a lower step coverage than the insulating film 123 is selected. For example, in a case of forming the insulating film 123 using TEOS SiO₂, it is possible to select SiOC as the material for the insulating film 128. For example, in a case of forming the insulating film 123 using SiOC, it is possible to select SiH₄ SiO₂ as the material for the insulating film 128.

For example, it is possible to manufacture the wiring structure 100A in the following manner.

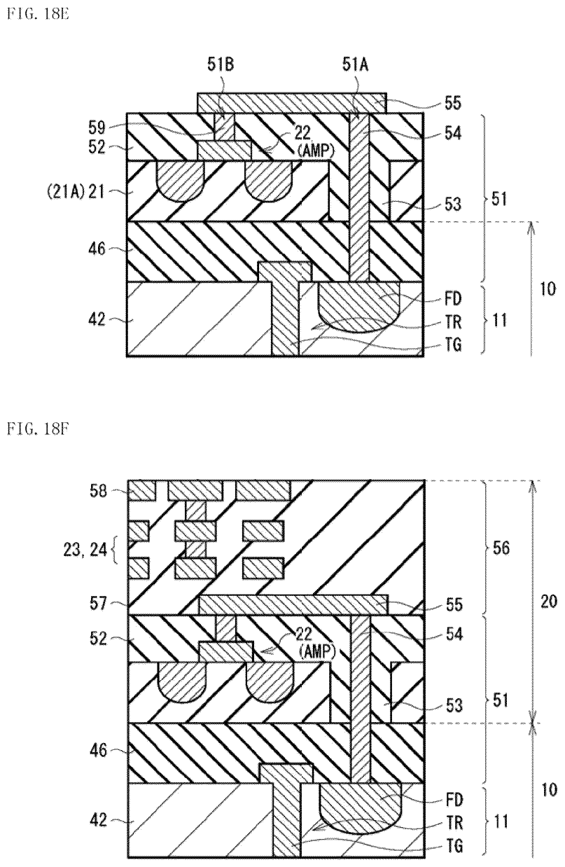

First, as in the first embodiment described above, as illustrated in FIG. 20A, for example, the insulating film 123 including, for example, TEOS SiO₂ and having a thickness of, for example, 10 nm to 500 nm is formed using, for example, a CVD method. This closes the opening H2, resulting in the formation of the air gap G1, one each between the wiring 112X2 and the wiring 112X3, between the wiring 112X3 and the wiring 112X4, and between the wiring 112X4 and the wiring 112V5.

Next, as illustrated in FIG. 20B, the insulating film 123 including, for example, SiOC, which has a lower step coverage than TEOS SiO₂ and having a thickness of, for example, 100 nm to 500 nm is formed on the insulating film 123, using the CVD method, for example. This results in the formation of the air gap G2 of minute size above the air gap G1.

Next, as illustrated in FIG. 20C, the insulating film 125 including, for example, SiOₓ, which has a thickness of 200 nm to 300 nm is formed on the insulating film 124, using the CVD method, for example, Then, the insulating film 125 is polished to have a planarized surface, using a CMP method, for example. Then, as in the first embodiment described above, an insulating film 126 and a conductive layer 127 including a barrier metal 127A and a metal film 127B are formed. Finally, the barrier metal 127A and the metal film 127B formed on the insulating film 126 are removed by polishing, thereby forming a planar surface in which the insulating film 126 and the conductive layer 127 are included in the same plane. Thus, the wiring structure 100A illustrated in FIG. 19 is completed.

In this manner, in the present embodiment, an insulating film 128 including an oxide film having a lower step coverage than the insulating film 123 is formed on the insulating film 123 having the air gap G1. This results in the formation of the air gap G2 above the air gap G1, thereby reducing the capacitance between and near the wirings.

Thus, the wiring structure 100A of the present embodiment makes it possible to reduce the wiring capacitance of the entire structure. In addition, for example, for the imaging element 1 to which the wiring structure 100 of the present embodiment is applied, it is possible to reduce the wiring capacitance between and near the wirings for the plurality of vertical signal lines 24 extending vertically across the pixel region 13.

### 3. Third Embodiment

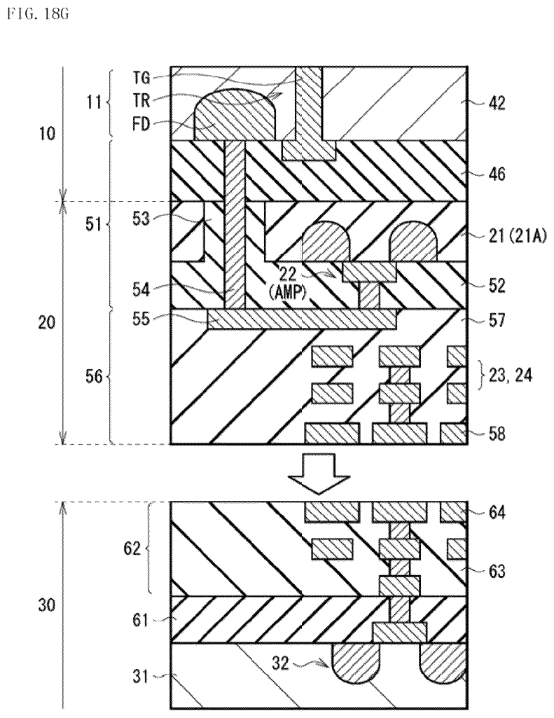

FIG. 21 schematically illustrates an example of a vertical cross-sectional configuration of a wiring structure (wiring structure 100B) according to a third embodiment of the present disclosure. For example, as in the second embodiment described above, the wiring structure 100B has a multilayer wiring configuration in which a plurality of wiring layers is laminated, and is applicable to, for example, the imaging element 1 described later.

The wiring structure 100B includes a wiring layer 112 including a plurality of wirings (for example, the wiring 112X1 to the wiring 112X6) extending in one direction (for example, in a Y-axis direction). The wiring structure 100B includes a barrier film 121 and insulating films 122 and 123, which are laminated on the wiring layer 112 in order. For example, the barrier film 121 extends over the wiring layer 112 and has an end surface S121, for example, on each of the wiring 112X2 and the wiring 112X5. The insulating film 122 is provided on the barrier film 121 and further extends to continuously cover a surface exposed in the opening H2, that is, an upper surface and a side surface of the wiring 112X2 to the wiring 112X5 as well as a bottom surface of the opening H2. The insulating film 123 is laminated above the barrier film 121 and is also provided to fill the opening H2 between each adjacent wiring (for example, between the adjacent wirings 112X2 and 112X3, between the wirings 112X3 and 112X4, and between the wirings 112X4 and 112X5).

In the wiring structure 100B, of the barrier metal 112A included in the wiring 112X1 to the wiring 112X6 and covering the side surface and the bottom surface of the metal film 112B, the barrier metal 112A of the wiring exposed in the opening H2 from the wiring 112X2 to the wiring 112X5 is partially retracted toward the bottom surface as illustrated in FIG. 21. This results in a step in the side surface of the wiring 112X2 to the wiring 112X5. In the present embodiment, the air gap G2 is formed in a self-aligned manner above the air gap G1 due to this step when the opening H2 is closed.

For example, it is possible to manufacture the wiring structure 100B in the following manner.

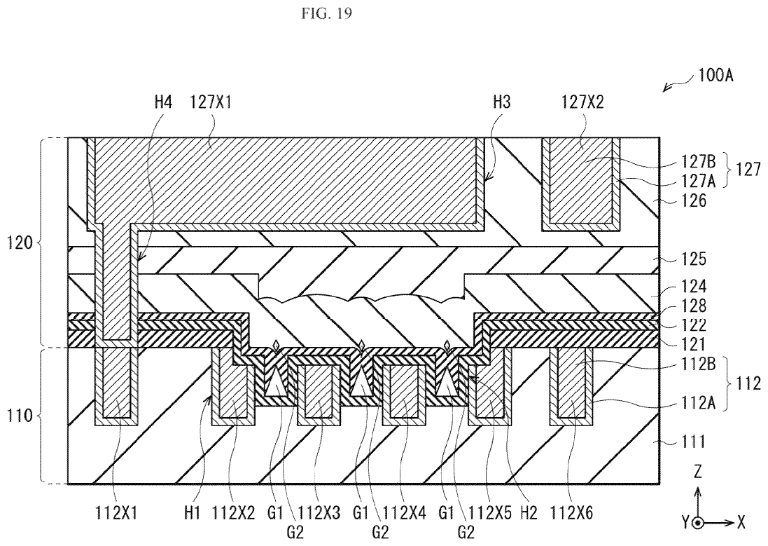

First, as in the first embodiment described above, as illustrated in FIG. 3C, for example, a portion exposed from the resist film 131, including the barrier film 121, a portion of the wiring 112X2 to the wiring 112X5, and the insulating film 111, is dry etched to create the opening H2. Subsequently, as illustrated in FIG. 22A, the barrier metal 112A of the wiring 112X2 to the wiring 112X5 is retracted toward the bottom by further performing excess dry etching.

Next, as in the first embodiment described above, the insulating film 122 is formed, and then, as illustrated in FIG. 22B, the insulating film 123 including, for example, SiOC or silicon nitride and having a thickness of, for example, 10 nm to 500 nm is formed, for example, using a CVD method. At this time, the opening H2 is closed by the insulating film 123, resulting in the formation of the air gap G1, one each between the wiring 112X2 and the wiring 112X3, between the wiring 112X3 and the wiring 112X4, and between the wiring 112X4 and the wiring 112V5. At the step formed by the retraction of the barrier metal 112A, a pinch-off occurs, resulting in the formation of an air gap G2 of minute size above the air gap G1.

Next, as illustrated in FIG. 22C, the insulating film 125, for example, including SiOₓ and having a thickness of 200 nm to 300 nm is formed on the insulating film 123, using a CVD method, for example. Then, the insulating film 125 is polished to have a planarized surface, using a CMP method, for example. Then, as in the first embodiment described above, an insulating film 126 and a conductive layer 127 including a barrier metal 127A and a metal film 127B are formed. Finally, the barrier metal 127A and the metal film 127B that are formed on the insulating film 126 are removed by polishing, thereby forming a planar surface in which the insulating film 126 and the conductive layer 127 are included in the same plane. Thus, the wiring structure 100B illustrated in FIG. 21 is completed.

In this manner, in the present embodiment, the barrier metal 112A of the wiring 112X2 to the wiring 112X5 that is exposed in the opening H2 is partially retracted toward the bottom surface, thereby forming a step on the side surface of the wiring 112X2 to the wiring 112X5. Accordingly, when the opening H2 is closed, the air gap G2 is formed in a self-aligned manner above the air gap G1 due to this step, reducing the capacitance between the wirings and an adjacent region thereof.

Thus, the wiring structure 100B of the present embodiment makes it possible to reduce the wiring capacitance of an entire structure. In addition, for example, for the imaging element i to which the wiring structure 100 of the present embodiment is applied, it is possible to reduce the wiring capacitance between and near the wirings for the plurality of vertical signal lines 24 extending vertically across the pixel region 13.

### 4. Modification Examples

### 4-1. Modification Example 1

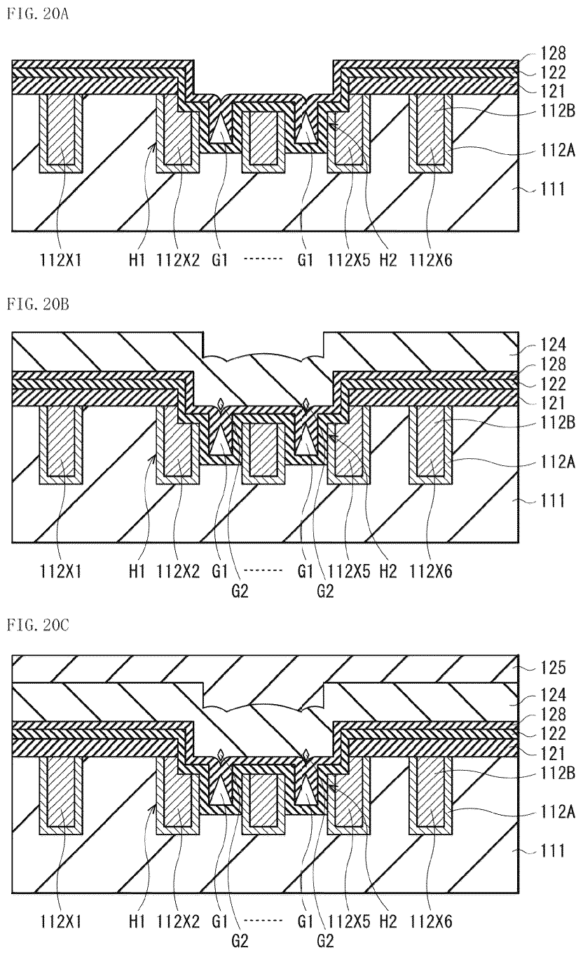

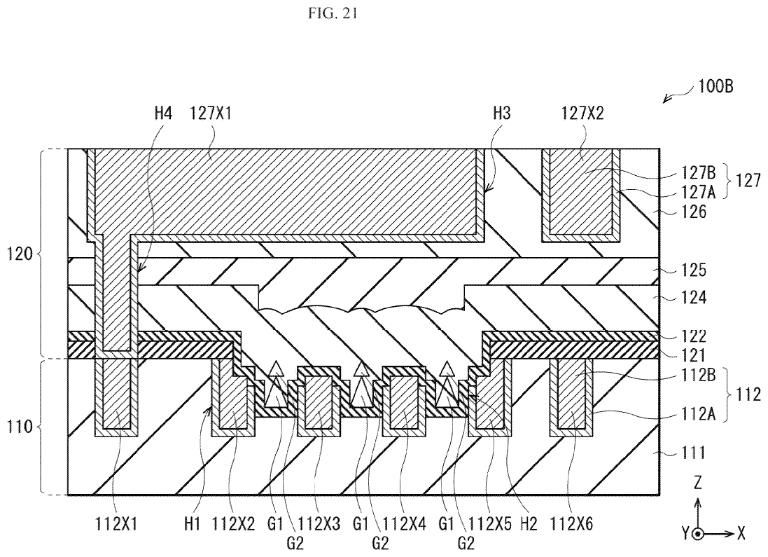

FIG. 23 schematically illustrates an example of a vertical cross-sectional configuration of a wiring structure (wiring structures 100A, 100B, 100C, and 100D) according to modification example 1 of the present disclosure. FIG. 24 schematically illustrates another example of a vertical cross-sectional configuration of the wiring structure (wiring structures 100A, 100B, 100C, and 100D) according to the modification example 1 of the present disclosure. A shape of the air gap G1 between each wiring from the wiring 112X2 to the wiring 112X5 is not limited to the shape illustrated in FIG. 1, etc.

For example, as illustrated in FIG. 23, a bottom of the air gap G1 may have substantially the same depth as a bottom of the wiring 112X2 to the wiring 112X5. Alternatively, as illustrated in FIG. 24, the bottom of the air gap G may have a larger depth than the bottom of the wirings 112X2 to 112X5. Other than this, although not illustrated, an upper surface of the air gap G may have a larger height than an upper surface of the wiring 112X2 to the wiring 112X5.

This makes it possible to further enhance an effect of reducing interwiring parasitic capacitance and electrical reliability (TDDB).

In addition, the air gap G may extend to the bottom of the wirings 112X2 to 112X5. Furthermore, the air gap G may extend from the bottom of the wirings 112X2 to 112X5 and may be continuous with each other at the bottom of the wirings 112X2 to 112X5. This allows a reduction in interwiring parasitic capacitance in the lamination direction in addition to a reduction in interwiring parasitic capacitance in a planar direction.

### 4-2. Modification Example 2

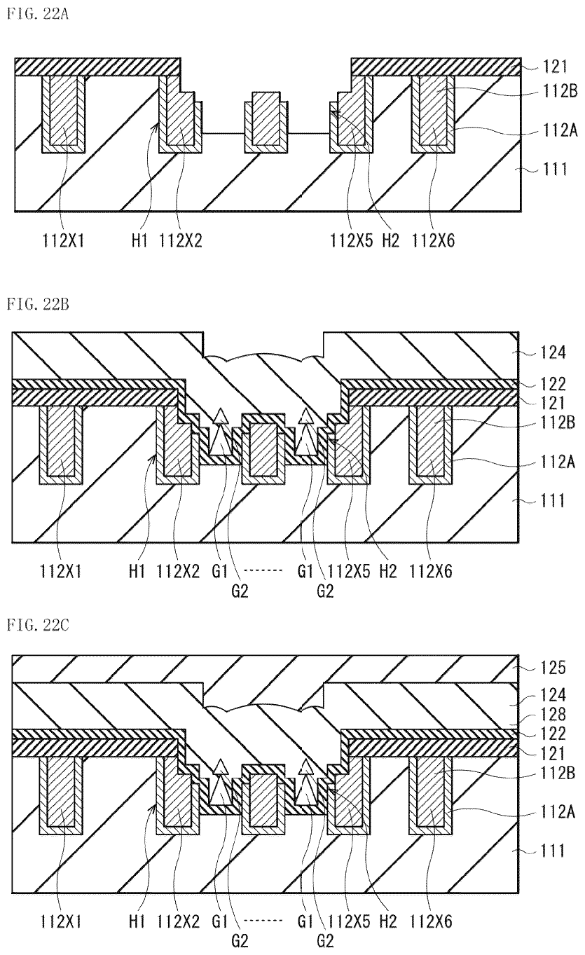

FIG. 25 illustrates an example of a vertical cross-sectional configuration of an imaging element (imaging element 1) according to one modification example (modification example 2) of the above embodiments, etc. In the present modification example, the transfer transistor TR has a planar transfer gate TG. For this reason, the transfer gate TG is formed only on the surface of the semiconductor substrate 11 without penetrating through the p-well layer 42. Even in a case where the planar type transfer gate TG is used for the transfer transistor TR, the imaging element 1 has an effect similar to the effect of the first embodiment described above.

### 4-3. Modification Example 3

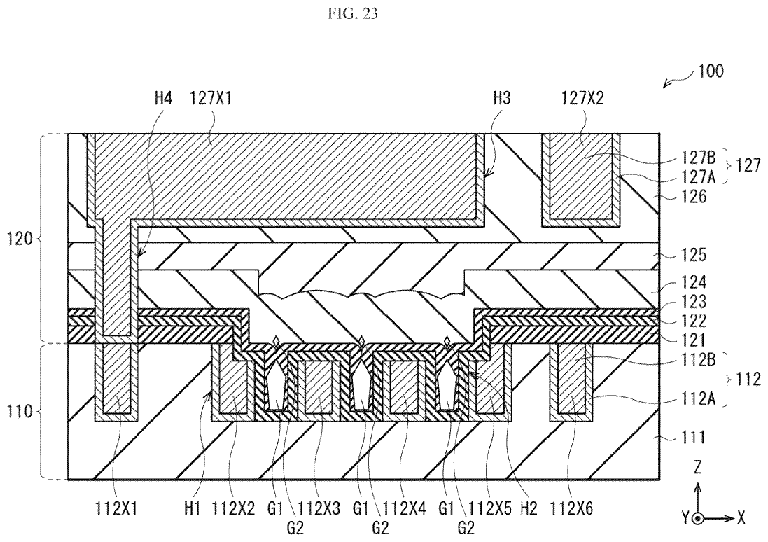

FIG. 26 illustrates an example of a vertical cross-sectional configuration of an imaging element (imaging element 1) according to one modification example (modification example 3) of the above embodiments, etc. In the present modification example, the second substrate 20 and the third substrate 30 are electrically coupled to each other in a region opposed to a peripheral region 14 in the first substrate 10. The peripheral region 14 corresponds to a frame region of the first substrate 10 and is provided at a periphery of the pixel region 13. In the present modification example, the second substrate 20 includes a plurality of pad electrodes 58 in a region opposed to the peripheral region 14, and the third substrate 30 includes a plurality of pad electrodes 64 in the region opposed to the peripheral region 14. The second substrate 20 and the third substrate 30 are electrically coupled to each other by bonding the pad electrodes 58 and 64 in the region opposed to the peripheral region 14.

Thus, in the present modification example, the second substrate 20 and the third substrate 30 are electrically coupled to each other by bonding the pad electrodes 58 and 64 in the region opposed to the peripheral region 14. This makes it possible to reduce a risk of interfering with a miniaturization of area per pixel compared to a case of bonding the pad electrodes 58 and 64 in the region opposed to the pixel region 13. Accordingly, in addition to the effects of the first embodiment described above, it is possible to provide the imaging element 1 having a three-layer configuration with a chip size equivalent to a previous size without interfering with the miniaturization of the area per pixel.

### 4-4. Modification Example 4

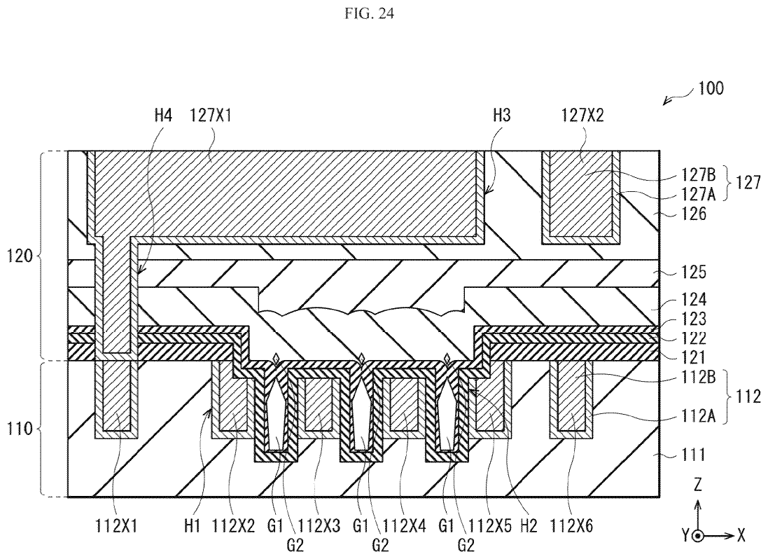

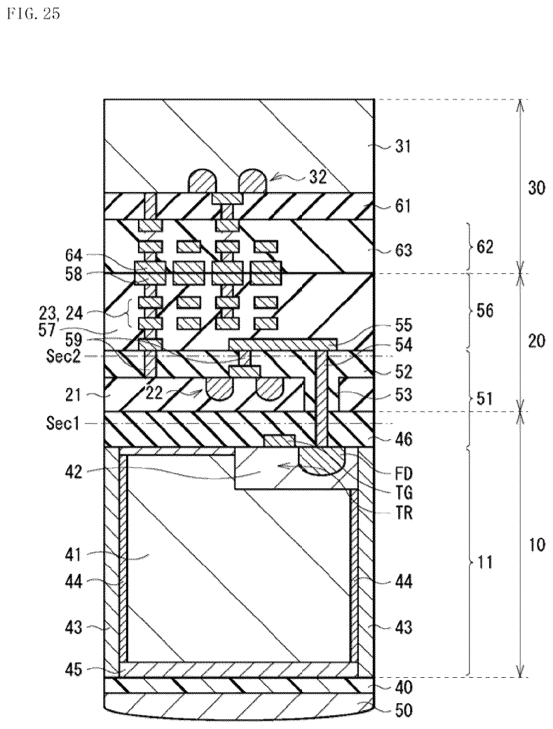

FIG. 27 illustrates an example of a vertical cross-sectional configuration of an imaging element (imaging element 1) according to one modification example (modification example 4) of the above embodiments, etc. FIG. 28 illustrates another example of the vertical cross-sectional configuration of the imaging element (imaging element 1) according to the modification example of the above embodiment (modification example 4). An upper view in each of FIGS. 27 and 28 is a modification example of a cross-sectional configuration at a cross section Sec1 of FIG. 1, and a lower view in FIG. 27 is a modification example of a cross-sectional configuration at a cross section Sec2 of FIG. 1. It is to be noted that in the upper cross-sectional view in each of FIGS. 27 and 28, a view illustrating a modification example of the surface configuration of the semiconductor substrate 11 of FIG. 1 is superimposed on the view illustrating a modification example of the cross-sectional configuration at the cross section Sec1 of FIG. 1, and the insulating layer 46 is omitted. In addition, in the lower cross-sectional view in FIGS. 27 and 28, a view illustrating a modification example of a surface configuration of the semiconductor substrate 21 is superimposed on a view illustrating a modification example of the cross-sectional configuration at the cross section Sec2 of FIG. 1.

As illustrated in FIGS. 27 and 28, the plurality of through wirings 54, the plurality of through wirings 48, and the plurality of through wirings 47 (a plurality of dots arranged in a matrix in the figure) are arranged in a belt-like shape in the first direction V (a horizontal direction in FIGS. 27 and 28) in the plane of the first substrate 10. It is to be noted that FIGS. 27 and 28 illustrate an example of a case where the plurality of through wirings 54, the plurality of through wirings 48, and the plurality of through wirings 47 are arranged in two columns in the first direction V. In the four sensor pixels 12 sharing the readout circuit 22, the four floating diffusions FD are arranged adjacent to each other, for example, via the element separation section 43. In the four sensor pixels 12 sharing the readout circuit 22, the four transfer gates TG (TG1, TG2, TG3, and TG4) are arranged to surround the four floating diffusions FD, for example, in a ring shape by the four transfer gates TG.

The insulating layer 53 includes a plurality of blocks extending in the first direction V. The semiconductor substrate 21 includes a plurality of blocks 21A having an island shape, and the plurality of blocks 21A extends in the first direction V while being arranged side by side in the second direction H orthogonal to the first direction V via the insulating layer 53. For example, each block 21A includes a reset transistor RST, an amplifying transistor AMP, and a selection transistor SEL. For example, one readout circuit 22 shared by the four sensor pixels 12 is not disposed directly opposed to the four sensor pixels 12 but is displaced in the second direction H.

In FIG. 27, the one readout circuit 22 shared by the four sensor pixels 12 includes, on the second substrate 20, a reset transistor RST, an amplifying transistor AMP, and a selection transistor SEL in a region that is displaced in the second direction H from a region opposed to the four sensor pixels 12. For example, the one readout circuit 22 shared by the four sensor pixels 12 includes the amplifying transistor AMP, the reset transistor RST, and the selection transistor SEL in one block 21A.

In FIG. 28, the one readout circuit 22 shared by the four sensor pixels 12 includes, on the second substrate 20, the reset transistor RST, the amplifying transistor AMP, the selection transistor SEL and the FD transfer transistor FDG in the region that is displaced in the second direction H from a region opposed to the four sensor pixels 12. For example, the one readout circuit 22 shared by the four sensor pixels 12 includes the amplifying transistor AMP, the reset transistor RST, the selection transistor SEL, and the FD transfer transistor FDG in one block 21A.

In the present modification example, for example, the one readout circuit 22 shared by the four sensor pixels 12 is not disposed directly opposed to the four sensor pixels 12 but is displaced in the second direction H from the position directly opposed to the four sensor pixels 12. In such a case, this allows the wiring 25 to be shorter or allows the wiring 25 to be omitted to configure the source of the amplifier transistor AMP and the drain of the selection transistor SEL in a common impurity region. As a result, it is possible to reduce the size of the readout circuit 22 or increase the size of another point in the readout circuit 22.

### 4-5. Modification Example 5

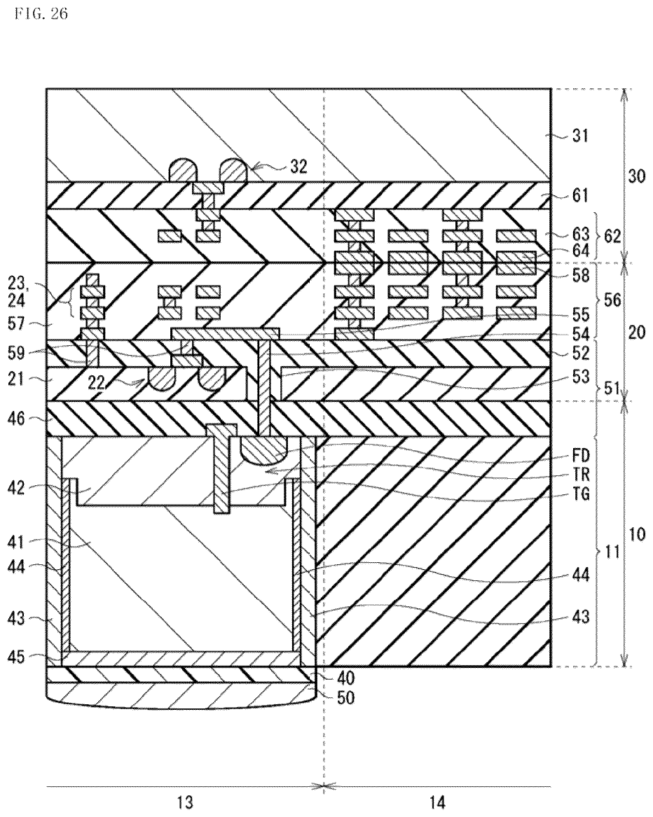

FIG. 29 illustrates an example of a horizontal cross-sectional configuration of an imaging element (imaging element 1) according to one modification example (modification example 5) of the above embodiments, etc. FIG. 29 illustrates a modification example of the cross-sectional configuration in FIG. 12.

In the present modification example, the semiconductor substrate 21 includes a plurality of blocks 21A having an island shape and arranged side by side in the first direction V and in the second direction H via the insulating layer 53. For example, each block 21A includes the reset transistor RST, the amplifying transistors AMP, and the selection transistors SEL as a set. In such a case, it is possible to suppress crosstalk between the readout circuits 22 adjacent to each other by the insulating layer 53, thereby making it possible to suppress resolution degradation on a reproduced image or image quality degradation due to color mixing.

### 4-6. Modification Example 6

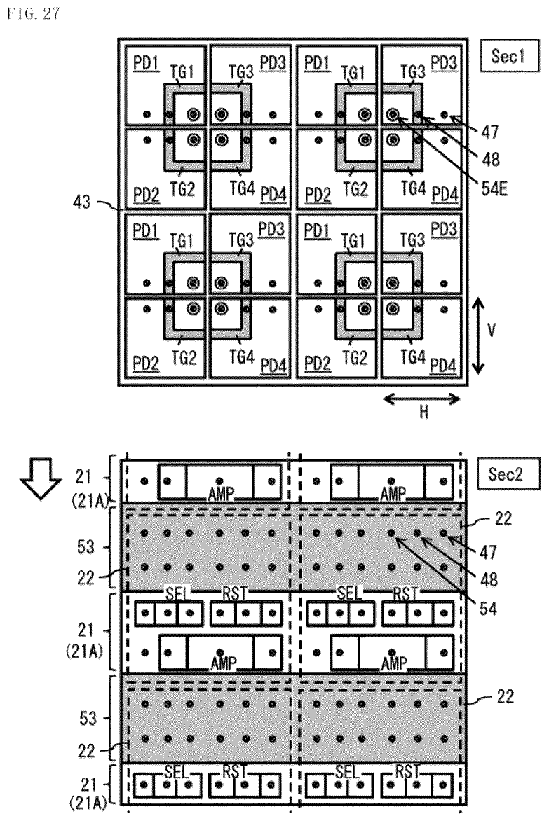

FIG. 30 illustrates an example of a horizontal cross-sectional configuration of an imaging element (imaging element 1) according to one modification example (modification example 6) of the above embodiments, etc. FIG. 30 illustrates a modification example of the cross-sectional configuration in FIG. 29.

In the present modification example, for example, one readout circuit 22 shared by four sensor pixels 12 is not disposed directly opposed to the four sensor pixels 12 but is displaced in the first direction V. Furthermore, in the present modification example, as in modification example 9, the semiconductor substrate 21 includes a plurality of blocks 21A having an island shape and arranged side by side in the first direction V and the second direction H via the insulating layer 53. For example, each block 21A includes the reset transistor RST, the amplifying transistor AMP, and the selection transistor SEL as a set. Furthermore, in the present modification example, the plurality of through wirings 47 and the plurality of through wirings 54 are also arranged in the second direction H. Specifically, the plurality of through wirings 47 is disposed between the four through wirings 54 sharing one readout circuit 22 and the four through wirings 54 sharing another readout circuit 22 that is adjacent to the one readout circuit 22 in the second direction H. In such a case, it is possible to suppress crosstalk between the readout circuits 22 adjacent to each other by the insulating layer 53 and the through wirings 47, thereby making it possible to suppress resolution degradation on a reproduced image and image quality degradation due to color mixing.

### 4-7. Modification Example 7

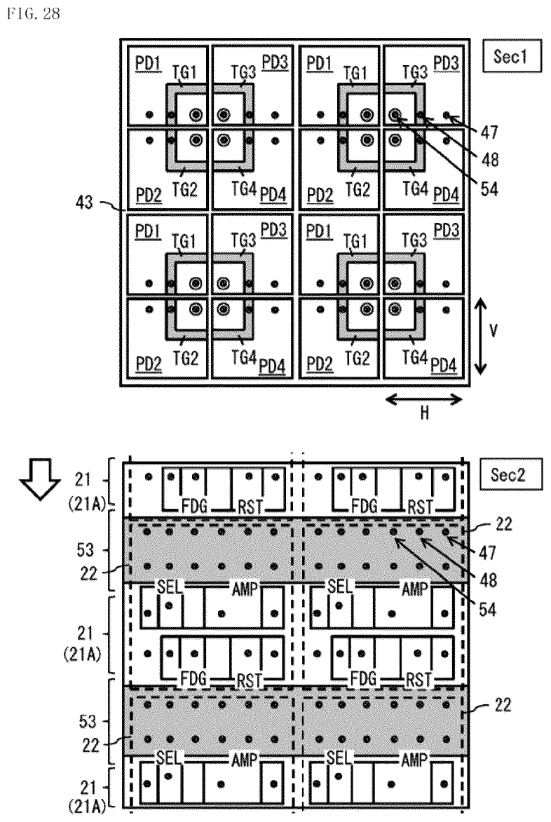

FIG. 31 illustrates an example of a horizontal cross-sectional configuration of an imaging element (imaging element 1) according to one modification example (modification example 7) of the above embodiments, etc. FIG. 31 illustrates a modification example of the cross-sectional configuration in FIG. 12.

In the present modification example, the first substrate 10 has a photodiode PD and a transfer transistor TR for each sensor pixel 12, and shares a floating diffusion FD one for every four sensor pixels 12. Accordingly, in the present modification example, the through wiring 54 is provided one for every four sensor pixels 12.

In a plurality of sensor pixels 12 arranged in a matrix, four sensor pixels 12 corresponding to a region, which is obtained by displacing, in the first direction V by one sensor pixel 12, a unit region corresponding to the four sensor pixels 12 sharing one floating diffusion FD, is to be referred to as four sensor pixels 12A for the sake of convenience. At this time, in the present modification example, the first substrate 10 shares the through wiring 47 for every four sensor pixels 12A. Accordingly, in the present modification example, the through wiring 47 is provided one for every four sensor pixels 12A.

In the present modification example, the first substrate 10 has the element separation section 43 that separates the photodiode PD and the transfer transistor TR for each sensor pixel 12. The element separation section 43 does not completely surround the sensor pixels 12 when viewed from the normal direction of the semiconductor substrate 11, and has a gap (unformed region) near the floating diffusion FD (the through wiring 54) and the through wiring 47. In addition, the gap allows the four sensor pixels 12 to share one through wiring 54 or allows the four sensor pixels 12A to share one through wiring 47. In the present modification example, the second substrate 20 has the readout circuit 22 one for every four sensor pixels 12 sharing the floating diffusion FD.

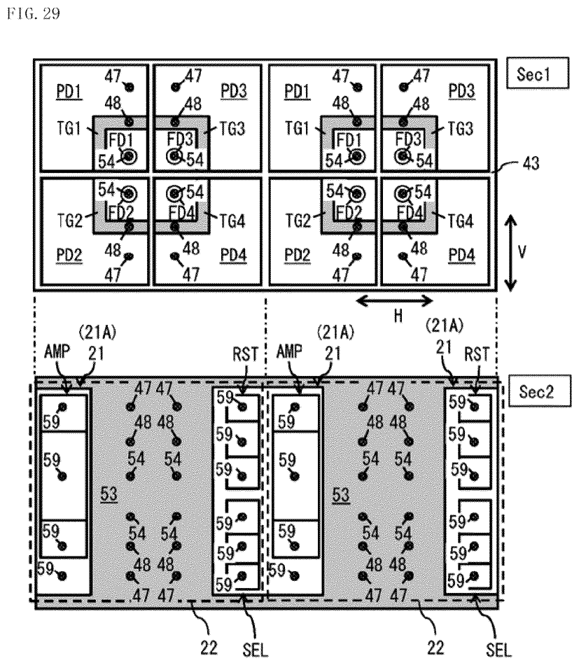

FIG. 32 illustrates another example of a horizontal cross-sectional configuration of the imaging element 1 according to the present modification example. FIG. 32 illustrates a modification example of the cross-sectional configuration in FIG. 30. In the present modification example, the first substrate 10 includes the photodiode PD and the transfer transistor TR for each sensor pixel 12, and shares the floating diffusion FD one for every four sensor pixels 12. Furthermore, the first substrate 10 includes the element separation section 43 that separates the photodiode PD and the transfer transistor TR for each sensor pixel 12.

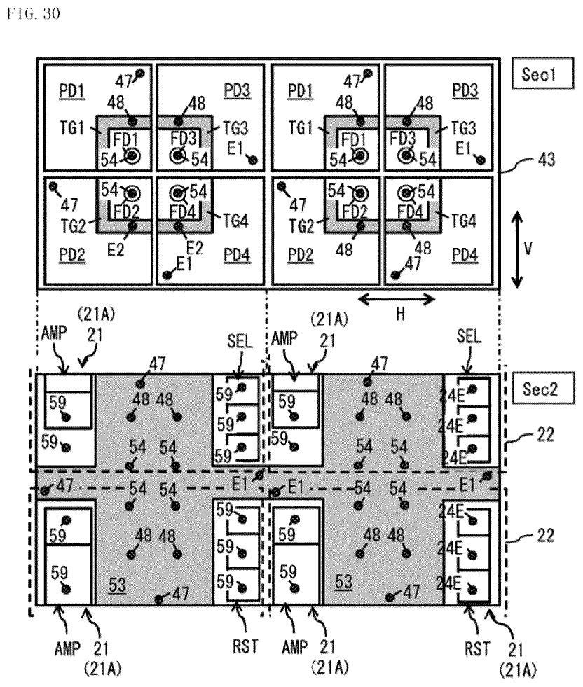

FIG. 33 illustrates another example of a horizontal cross-sectional configuration of the imaging element 1 according to the present modification example. FIG. 33 illustrates a modification example of the cross-sectional configuration in FIG. 31. In the present modification example, the first substrate 10 includes a photodiode PD and a transfer transistor TR for each sensor pixel 12, and shares the floating diffusion FD one for every four sensor pixels 12. Furthermore, the first substrate 10 includes the element separation section 43 that separates the photodiode PD and the transfer transistor TR for each sensor pixel 12.

### 4-8. Modification Example 8

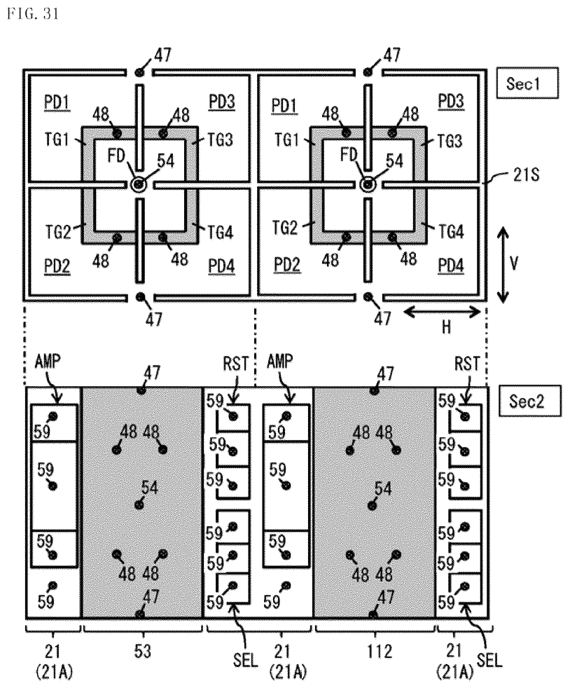

FIG. 34 illustrates an example of a circuit configuration of an imaging element (imaging element 1) according to one modification example (modification example 8) of the above embodiments, etc. The imaging element 1 according to the present modification example is a CMOS image sensor incorporated with a column-parallel ADC.

As illustrated in FIG. 34, the imaging element 1 according to the present modification example includes a pixel region 13 in which a plurality of sensor pixels 12 each including a photoelectric conversion section is arranged two-dimensionally in a matrix (that is, in a matrix-state). In addition to this, the imaging element 1 includes a vertical drive circuit 33, a column signal processing circuit 34, a reference voltage supply section 38, a horizontal drive circuit 35, a horizontal output line 37, and a system control circuit 36.

In this system configuration, on the basis of a master clock MCK, the system control circuit 36 generates a clock signal, a control signal, or the like that serves as a reference for an operation of the vertical drive circuit 33, the column signal processing circuit 34, the reference voltage supply section 38, and the horizontal drive circuit 35 or the like. The system control circuit 36 then supplies the clock signal, the control signal, or the like to the vertical drive circuit 33, the column signal processing circuit 34, the reference voltage supply section 38, and the horizontal drive circuit 35 or the like.

In addition, the vertical drive circuit 33 is formed on the first substrate 10 as well as each sensor pixel 12 in the pixel region 13, and is further formed on the second substrate 20 on which the readout circuit 22 is formed. The column signal processing circuit 34, the reference voltage supply 38, the horizontal drive circuit 35, the horizontal output line 37, and the system control circuit 36 are formed on the third substrate 30.

As the sensor pixel 12, for example, although an illustration thereof by the figure is omitted here, it is possible to use a configuration that includes, in addition to a photodiode PD, a transfer transistor TR that transfers an electric charge obtained by photoelectric conversion in the photodiode PD to the floating diffusion FD. In addition, as the readout circuit 22, for example, although an illustration thereof by the figure is omitted here, it is possible to use a three-transistor configuration including a reset transistor RST that controls a potential of the floating diffusion FD, an amplifier transistor AMP that outputs a signal in accordance with a potential of the floating diffusion FD, and a selection transistor SEL that performs pixel selection.

In the pixel region 13, each sensor pixel 12 is two-dimensionally arranged, and for this pixel arrangement in m rows and n columns, the pixel drive line 23 is provided for each row and the vertical signal line 24 is provided for each column. Each of the plurality of pixel drive lines 23 has an end coupled to each output end corresponding to each row of the vertical drive circuit 33. The vertical drive circuit 33 includes a shift register or the like, and controls a row address and row scanning of the pixel region 13 via the plurality of pixel drive lines 23.

For example, the column signal processing circuit 34 has an ADC (analog-to-digital conversion circuit) 34-1 to 34-m, which is provided for each pixel column of the pixel region 13, that is, each vertical signal line 24. The column signal processing circuit 34 converts, into a digital signal, an analog signal outputted on a column-by-column basis from each sensor pixel 12 in the pixel region 13, to output the digital signal.

For example, the reference voltage supply section 38 includes a DAC (digital-to-analog conversion circuit) 38A as a means of generating a reference voltage Vref of what is called a ramp (RAMP) waveform, a level of which varies in a sloping manner over time. It is to be noted that the means of generating a ramp-waveform reference voltage Vref is not limited to the DAC 38A.

Under the control of a control signal CS1 supplied by the system control circuit 36, the DAC 38A generates a ramp-waveform reference voltage Vref on the basis of a clock CK supplied by the system control circuit 36, and supplies the ramp-waveform reference voltage Vref to the ADCs 34-1 to 34-m in the column signal processing circuit 34.

It is to be noted that the ADCs 34-1 to 34-m are each configured to perform an AD conversion operation corresponding to each operation mode selectively between a normal frame rate mode using a progressive scan system to read out information from all of the sensor pixels 12, and a high-speed frame rate mode to set the frame rate N times higher, for example, two times higher than in the normal frame rate mode by setting an exposure time for the sensor pixel 12 to 1/N. This switching of operation modes is performed under the control of control signals CS2 and CS3 supplied by the system control circuit 36. In addition, instruction information for switching between the normal frame rate mode and the high-speed frame rate mode is supplied to the system control circuit 36 from an external system controller (not illustrated).

The ADCs 34-1 to 34-m all have the same configuration, and are described here with reference to the ADC 34-m as an example. The ADC 34-m includes a comparator 34A, an up/down counter (noted as U/DCNT in the figure) 34B that is a counting means, for example, a transfer switch 34C, and a memory device 34D.

The comparator 34A compares a signal voltage Vx of the vertical signal line 24 corresponding to a signal outputted from each sensor pixel 12 in an nth column of the pixel region 13 with the ramp-waveform reference voltage Vref supplied by the reference voltage supply section 38. For example, when the reference voltage Vref is greater than the signal voltage Vx, an output Vco becomes an “H” level, and when the reference voltage Vref is equal to or less than the signal voltage Vx, the output Vco becomes an “L” level.

The up/down counter 34B is an asynchronous counter and measures a comparison period from a start of a comparison operation to an end of the comparison operation in the comparator 34A by counting down (DOWN) or counting up (UP) in synchronization with the clock CK, which is supplied by the system control circuit 36 simultaneously with the DAC 18A under the control of the control signal CS2 supplied by the system control circuit 36.

Specifically, in the normal frame rate mode, in a reading operation to read out a signal from one sensor pixel 12, counting down is performed during a first reading operation to measure the comparison time during the first reading, and counting up is performed during a second reading operation to measure the comparison time during the second reading.

On the other hand, in the high-speed frame rate mode, a count result for the sensor pixel 12 in one row is held as is, and counting down is continuously performed for the sensor pixel 12 in a subsequent row, starting from a previous count result, thereby measuring the comparison time during the first reading, and counting up is performed during the second reading operation, thereby measuring the comparison time during the second reading operation.

Under the control of a control signal CS3 supplied by the system control circuit 36, in the normal frame rate mode, the transfer switch 34C is turned ON (closed) when the counting operation of the up/down counter 34B is completed for the sensor pixel 12 in one row, and transfers the count result of the up/down counter 34B to the memory device 34D.

On the other hand, for example, at a high frame rate of N=2, the up/down counter 34B remains OFF (open) when the counting operation of the up/down counter 34B is completed for the sensor pixel 12 in one row. Following this, when the counting operation of the up/down counter 34B for the sensor pixels 12 in a subsequent row is completed, the up/down counter 34B turns ON and transfers the count result of the up/down counter 34B for two vertical pixels to the memory device 34D.

In this manner, an analog signal, which is supplied per column by each sensor pixel 12 in the pixel region 13 via the vertical signal line 24, is converted into an N-bit digital signal by each operation of the comparator 34A and the up/down counter 34B in the ADCs 34-1 to 34-m, to be stored in the memory device 34D.

The horizontal drive circuit 35 includes a shift register or the like and controls the column address and column scanning of the ADCs 34-1 to 34-m in the column signal processing circuit 34. Under the control of this horizontal drive circuit 35, the N-bit digital signal that is AD-converted at each of the ADCs 34-1 to 34-m is sequentially read out to the horizontal output line 37, to be outputted as captured image data via the horizontal output line 37.

It is to be noted that, although not specifically illustrated by the figure because the following is not directly related to the present disclosure, it is also possible to provide, in addition to the components described above, a circuit or the like that performs various signal processing on the captured image data outputted via the horizontal output line 37.

The imaging element 1 incorporated with a column-parallel ADC according to the present modification example of the configuration described above makes it possible to selectively transfer the count result of the up/down counter 34B to the memory device 34D via the transfer switch 34C, thus making it possible to independently control the counting operation of the up/down counter 34B and the reading operation of the up/down counter 34B to read out the count result to the horizontal output line 37.

### 4-9. Modification Example 9

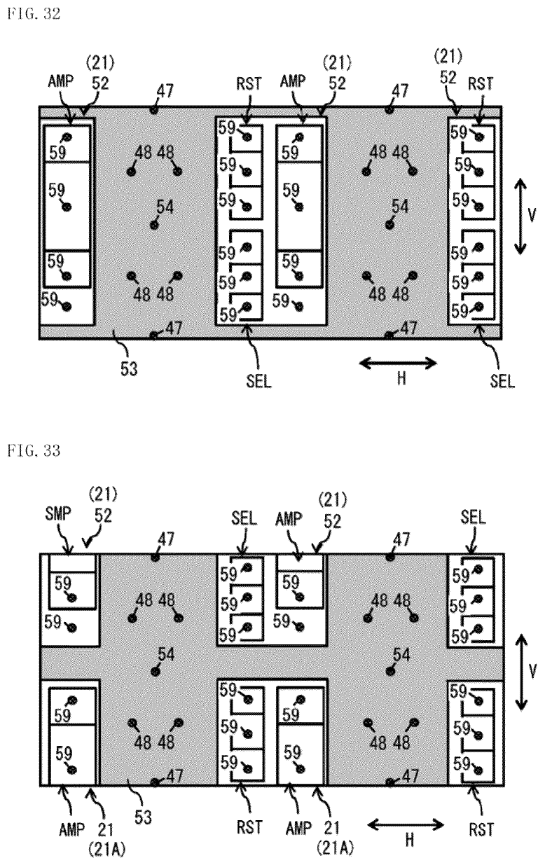

FIG. 35 illustrates an example of a configuration in which the imaging element of FIG. 34 includes three laminated substrates (the first substrate 10, the second substrate 20, and the third substrate 30). In the present modification example, in the first substrate 10, the pixel region 13 including a plurality of sensor pixels 12 is formed in a central portion, and the vertical drive circuit 33 is formed around the pixel region 13. In addition, in the second substrate 20, a readout circuit region 15 including a plurality of readout circuits 22 is formed in a central portion, and the vertical drive circuit 33 is formed around the readout circuit region 15. In the third substrate 30, the column signal processing circuit 34, the horizontal drive circuit 35, the system control circuit 36, the horizontal output line 37, and the reference voltage supply section 38 are formed. As in the above embodiments, etc., this avoids increasing the chip size or compromising area per pixel miniaturization due to the configuration in which the substrates are electrically coupled to each other. As a result, it is possible to provide the imaging element 1 having a three-layer configuration with a chip size equivalent to an existing chip size, without compromising the miniaturization of the area per pixel. It is to be noted that the vertical drive circuit 33 may be formed only on the first substrate 10 or may be formed only on the second substrate 20.

### 4-10. Modification Example 10

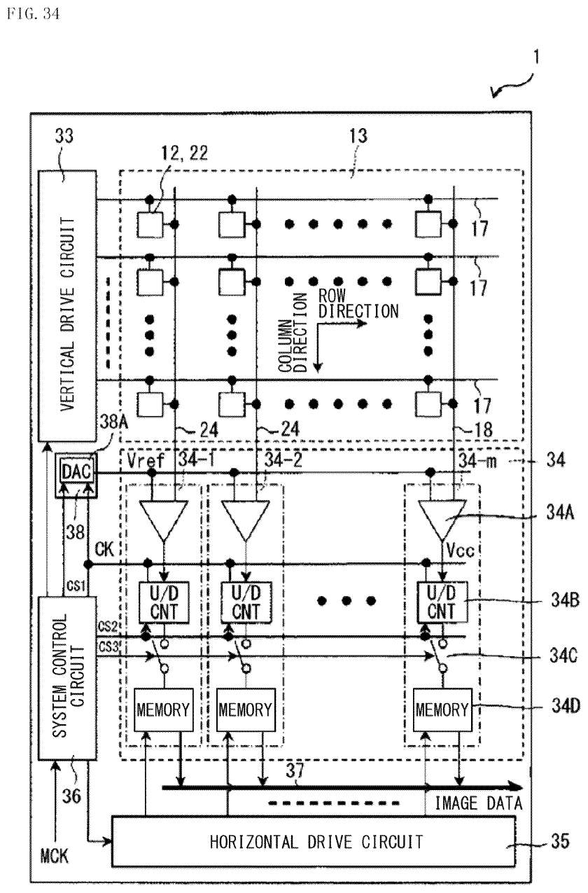

FIG. 36 illustrates an example of a cross-sectional configuration of an imaging element (imaging element 1) according to one modification example (modification example 10) of the above embodiments, etc. In the above embodiments, etc., the imaging element 1 is configured to include three laminated substrates (the first substrate 10, the second substrate 20, and the third substrate 30). However, the imaging element 1 may be configured to include two laminated substrates (the first substrate 10 and the second substrate 20). At this time, for example, the logic circuit 32 may be formed separately on the first substrate 10 and the second substrate 20 as illustrated in FIG. 36. Here, of the logic circuit 32, a circuit 32A, which is provided on the first substrate 10 side, includes a transistor having a gate configuration in which a high dielectric constant film including a material resistant to high temperature processing (for example, high-k) and a metal gate electrode are laminated. On the other hand, a circuit 32B, which is provided on the second substrate 20 side, includes, in a surface of an impurity diffusion region in contact with the source electrode and the drain electrode, a low-resistance region 26 including silicide that is formed by salicide (Self Aligned Silicide) processing such as CoSi2 or NiSi. The low-resistance region including silicide includes a compound of a material for the semiconductor substrate and a metal. This makes it possible to use high temperature processing such as thermal oxidation when forming the sensor pixel 12. In addition, of the logic circuit 32, in the circuit 32B provided on the second substrate 20 side, in a case where the low-resistance region 26 including silicide is provided in the surface of the impurity diffusion region in contact with the source electrode and the drain electrode, it is possible to reduce contact resistance. As a result, it becomes possible to increase calculation speed in the logic circuit 32.

### 4-11. Modification Example 11

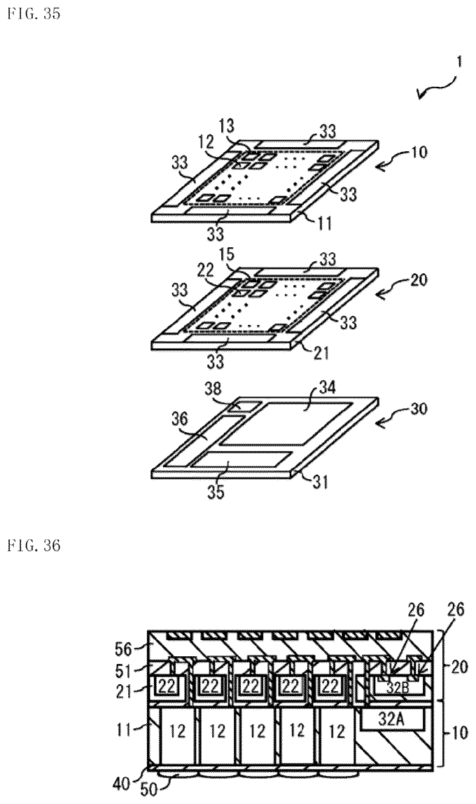

FIG. 37 illustrates a modification example of the cross-sectional configuration of the imaging element 1 according to one modification example (modification example 11) of the above embodiments, etc. The logic circuit 32 on the third substrate 30 according to the above embodiments, etc. may include, in the surface of the impurity diffusion region in contact with the source electrode and the drain electrode, a low-resistance region 39 including silicide that is formed by salicide (Self Aligned Silicide) processing such as CoSi2 and NiSi. This makes it possible to use high temperature processing such as thermal oxidation when forming the sensor pixel 12. In addition, in the logic circuit 32, in a case where the low-resistance region 39 including silicide is provided on the surface of the impurity diffusion region in contact with the source electrode and the drain electrode, it is possible to reduce contact resistance. As a result, it becomes possible to increase calculation speed in the logic circuit 32.

It is to be noted that in the above embodiments, etc., the conductivity type may be reversed. For example, in the description of the above embodiments, etc., p-type may be read as n-type and n-type may be read as p-type. In such a case, it is also possible to obtain an effect similar to an effect of the above embodiments, etc.

### 5. Application Example

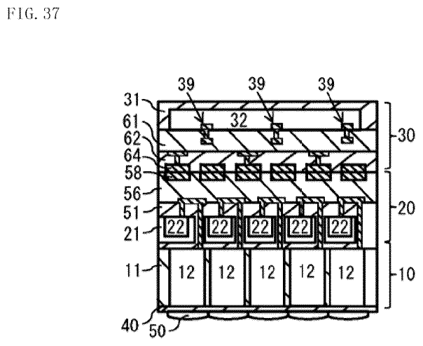

FIG. 38 illustrates an example of a schematic configuration of an imaging system 7 including an imaging element (imaging element 1) according to the above first to third embodiments and modification examples 1 to 11.

For example, the imaging system 7 is an imaging element such as a digital still camera or video camera, or an electronic device such as a portable terminal device such as a smartphone or tablet-type device, or the like. For example, the imaging system 7 includes an optical system 241, a shutter device 242, the imaging element 1, a DSP circuit 243, a frame memory 244, a display 245, a memory section 246, an operation section 247, and a power supply 248. In the imaging system 7, the shutter device 242, the imaging element 1, the DSP circuit 243, the frame memory 244, the display 245, the memory section 246, the operation section 247, and the power supply 248 are coupled to each other via a bus line 249.

The imaging element 1 outputs image data corresponding to entering light. The optical system 241 has one or more lenses, and guides light from a subject (entering light) to the imaging element 1 to form an image on a light-receiving surface of the imaging element 1. The shutter device 242 is disposed between the optical system 241 and the imaging element 1, and controls a light irradiation period and a light shielding period to the imaging element 1 in accordance with the control of the operation section 247. The DSP circuit 243 is a signal processing circuit that processes a signal (image data) outputted from the imaging element 1. The frame memory 244 temporarily holds the image data processed by the DSP circuit 243 on a frame-by-frame basis. For example, the display 245 includes a panel-type display device, such as a liquid crystal panel or an organic EL (Electro Luminescence) panel and displays a moving image or a still image captured by the imaging element 1. The memory section 246 records the image data of the moving or still image captured by the imaging element 1 onto a recording medium such as a semiconductor memory or a hard disk. The operation section 247 issues an operation command for various functions of the imaging system 7 in accordance with an operation by a user. The power supply 248 supplies, as appropriate, various power sources as power supplies for operating the imaging element 1, the DSP circuit 243, the frame memory 244, the display 245, the memory section 246, and the operation section 247 to these supply targets.

Next, an imaging procedure in the imaging system 7 will be described.

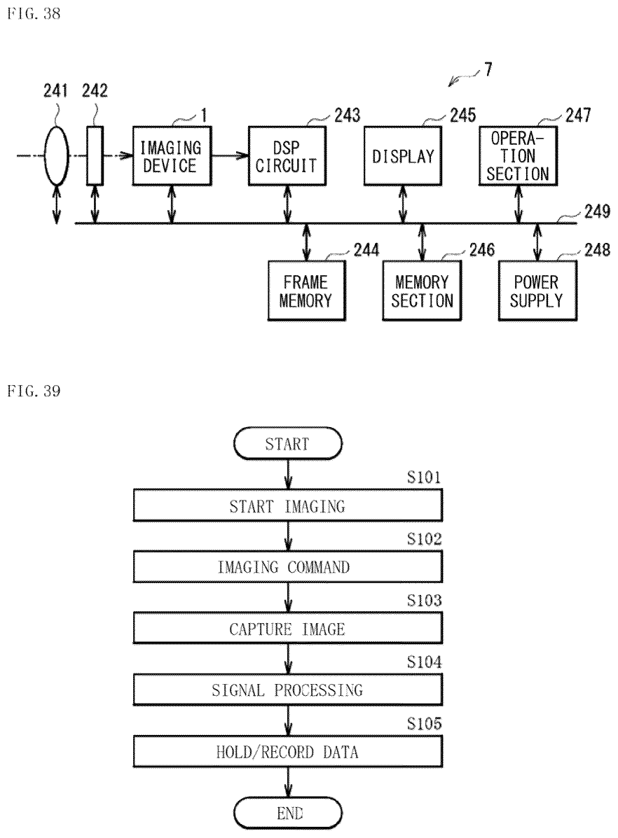

FIG. 39 illustrates an example of a flowchart of an imaging operation in the imaging system 7. A user gives an instruction to start imaging by operating the operation section 247 (step S101). Then, the operation section 247 transmits an imaging command to the imaging element 1 (step S102). When receiving the imaging command, the imaging element 1 (specifically, the system control circuit 36) executes imaging using a predetermined imaging method (step S103).

The imaging element 1 outputs, to the DSP circuit 243, light (image data) formed into an image on the light-receiving surface through the optical system 241 and the shutter device 242. Here, the image data is the data of the pixel signals of all pixels that is generated on the basis of the electric charge temporarily held on the floating diffusion FD. The DSP circuit 243 performs predetermined signal processing (for example, noise reduction processing) on the basis of the image data inputted from the imaging element 1 (step S104). The DSP circuit 243 causes the frame memory 244 to hold the image data on which the predetermined signal processing is performed, and the frame memory 244 causes the image data to be stored in the memory section 246 (step S105). In this manner, imaging is performed in the imaging system 7.

In the present application example, the imaging element 1 is applied to the imaging system 7. This enables the imaging element 1 to be smaller or higher definition, thus making it possible to provide a smaller or higher definition imaging system 7.

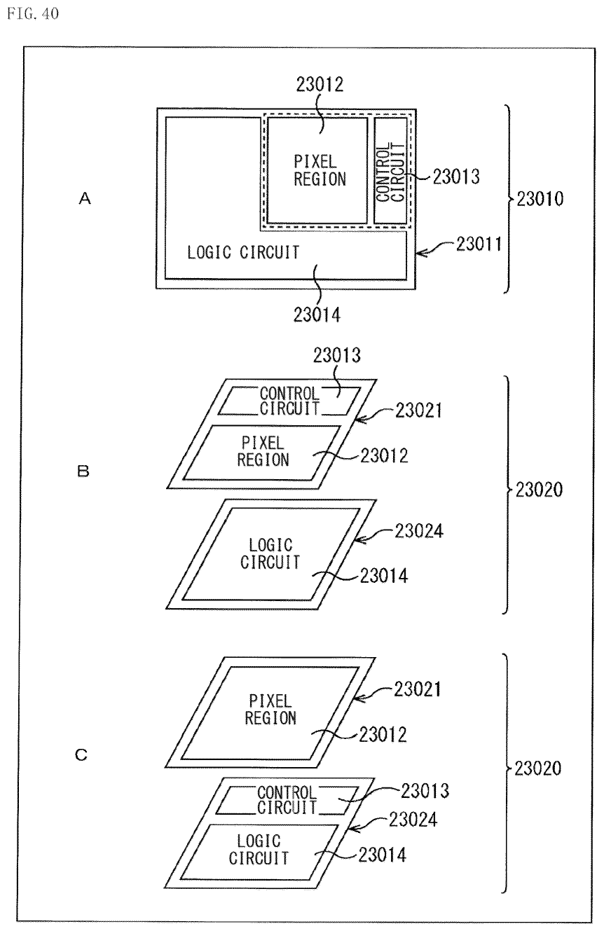

FIG. 40 illustrates an overview of a configuration example of a solid-state imaging element of a non-laminated type (solid-state imaging element 23210) and a solid-state imaging element of a laminated type (solid-state imaging element 23020) to which the technique of the present disclosure is applicable.

A of FIG. 40 illustrates an example of a schematic configuration of a solid-state imaging element of a non-laminated type. As illustrated in A of FIG. 40, the solid-state imaging element 23010 includes a single die (semiconductor substrate) 23011. This die 23011 includes a pixel region 23012 in which each pixel is arranged in an array, a control circuit 23013 that drives the pixel and performs other various controls, and a logic circuit 23014 that performs signal processing.

B and C of FIG. 40 each illustrate an example of a schematic configuration of a solid-state imaging element of a laminated type. As illustrated in B and C of FIG. 40, the solid-state imaging element 23020 includes two dies, that is, a sensor die 23021 and a logic die 23024 laminated and electrically coupled to be configured as a single semiconductor chip. These sensor die 23021 and logic die 23024 correspond to one specific example of the “first substrate” and the “second substrate” of the present disclosure.

In B of FIG. 40, the sensor die 23021 carries the pixel region 23012 and the control circuit 23013, and the logic die 23024 carries the logic circuit 23014 including a signal processing circuit that performs signal processing. Furthermore, for example, the sensor die 20321 may carry the readout circuit 22 or the like that is described earlier.

In C of FIG. 40, the sensor die 23021 carries the pixel region 23012, and the logic die 23024 carries the control circuit 23013 and the logic circuit 23014.

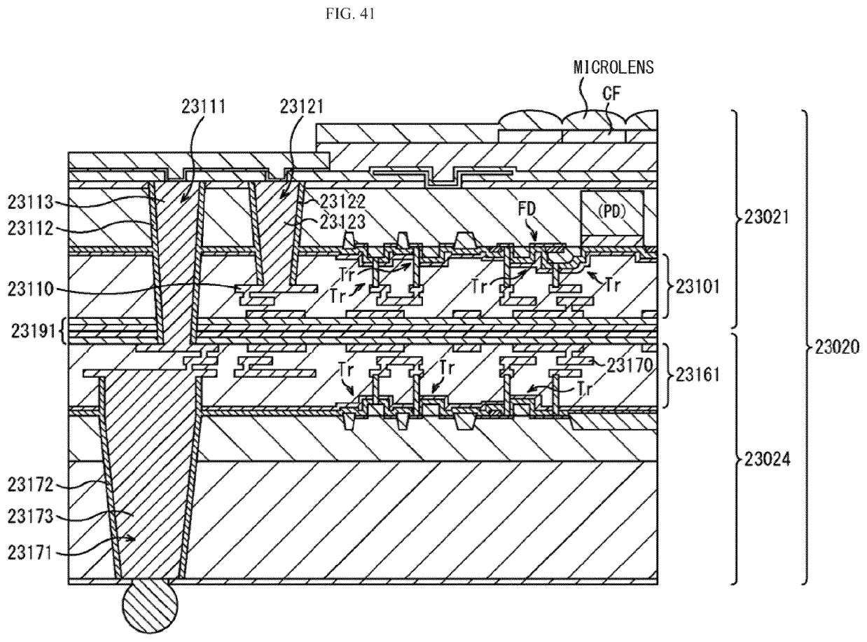

FIG. 41 is a cross-sectional view illustrating a first configuration example of the solid-state imaging element 23020 of a laminated type.

In the sensor die 23021, a PD (photodiode) included in a pixel to be included in the pixel region 23012, an FD (floating diffusion), a Tr (MOS FET), and a Tr that serves as the control circuit 23013 or the like are formed. Furthermore, in the sensor die 23021, a wiring layer 23101 including a plurality of layers, or three layers of wiring 23110 in this example is formed. It is to be noted that it is possible to provide the control circuit 23013 (the Tr serving as the control circuit 23013) in the logic die 23024 instead of providing the control circuit 23013 in the sensor die 23021.

In the logic die 23024, the Tr is formed to be included in the logic circuit 23014. Furthermore, in the logic die 23024, the wiring layer 23161 including a plurality of layers or three layers of wiring 23170 in this example is formed. In addition, the logic die 23024 has a contact hole 23171 in which an insulating film 23172 is formed on an inner wall surface thereof, and a coupling conductor 23173 to be coupled to the wiring 23170 or the like is buried in the contact hole 23171.

The sensor die 23021 and the logic die 23024 are bonded together with the wiring layers 23101 and 23161 facing each other, thereby configuring the solid-state imaging element 23020 of a laminated type in which the sensor die 23021 and the logic die 23024 are laminated. A protective film 23191 or the like is formed on the surface in which the sensor die 23021 and the logic die 23024 are bonded together.

The sensor die 23021 has a contact hole 23111 that penetrates through the sensor die 23021 from a back surface side (a side on which light enters the PD) (upper side) of the sensor die 23021 to reach the wiring 23170 in a top layer of the logic die 23024. Furthermore, near the contact hole 23111, the sensor die 23021 has a contact hole 23121 that reaches the wiring 23110 in a first layer from the back surface side of the sensor die 23021. An insulating film 23112 is formed on the inner wall surface of the contact hole 23111, and an insulating film 23122 is formed on the inner wall surface of the contact hole 23121. Then, the coupling conductors 23113 and 23123 are buried in the contact holes 23111 and 23121, respectively. The coupling conductor 23113 and the coupling conductor 23123 are electrically coupled to each other on the back surface side of the sensor die 23021, thereby electrically coupling the sensor die 23021 and the logic die 23024 via the wiring layer 23101, the contact hole 23121, the contact hole 23111, and the wiring layer 23161.

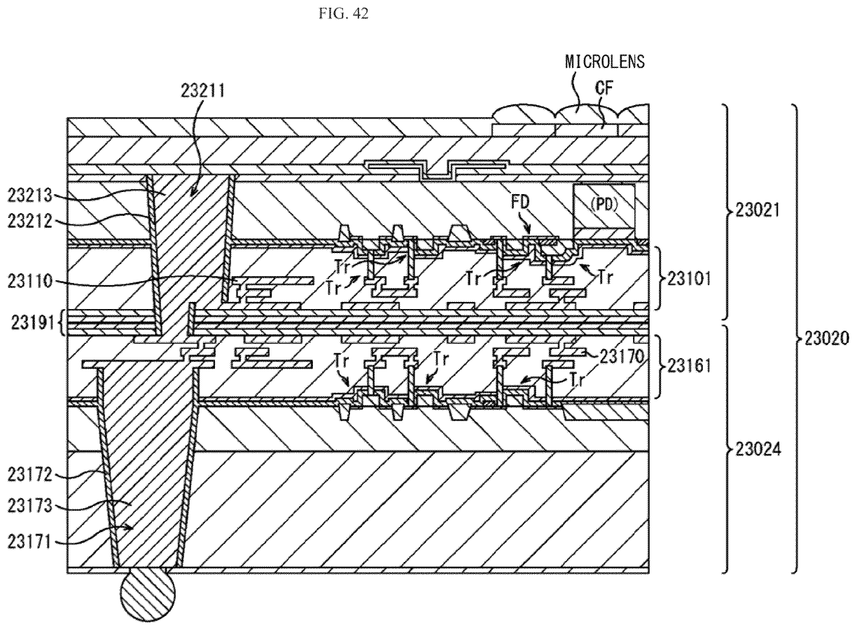

FIG. 42 is a cross-sectional view illustrating a second configuration example of the solid-state imaging element 23020 of a laminated type.

In the second configuration example of the solid-state imaging element 23020, ((the wiring 23110 in) the wiring layer 23101 of) the sensor die 23021 and ((the wiring 23170 in) the wiring layer 23161 of) the logic die 23024 are electrically coupled to each other through one contact hole 23211 created in the sensor die 23021.

In other words, in FIG. 42, the contact hole 23211 is formed to penetrate through the sensor die 23021 from the back surface side of the sensor die 23021 to reach the wiring 23170 in the top layer of the logic die 23024 and also to reach the wiring 23110 in the top layer of the sensor die 23021. An insulating film 23212 is formed on the inner wall surface of the contact hole 23211, and a coupling conductor 23213 is buried in the contact hole 23211. In FIG. 41 described earlier, the sensor die 23021 and the logic die 23024 are electrically coupled to each other through the two contact holes 23111 and 23121. In FIG. 42, the sensor die 23021 and the logic die 23024 are electrically coupled to each other through one contact hole 23211.

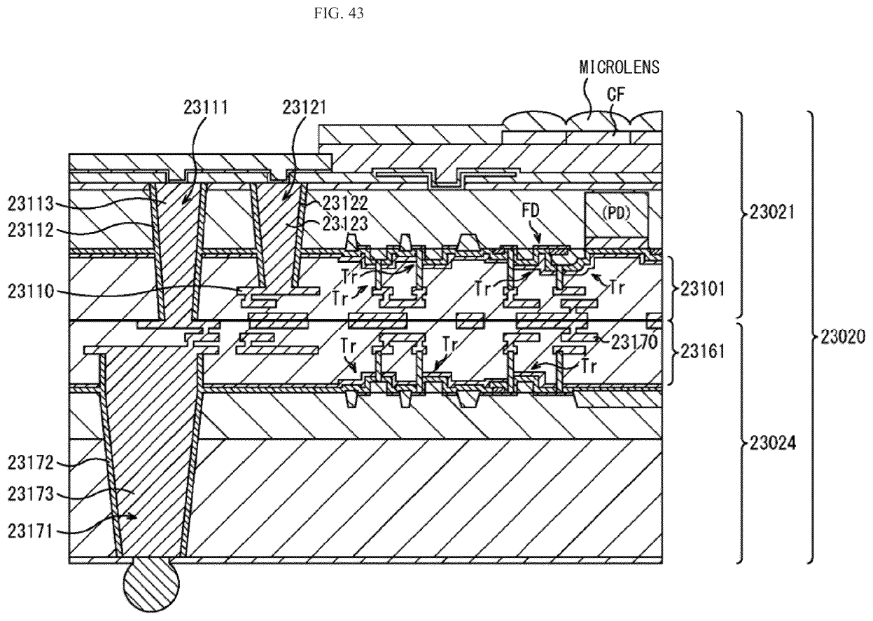

FIG. 43 is a cross-sectional view illustrating a third configuration example of the solid-state imaging element 23020 of a laminated type.

The solid-state imaging element 23020 of FIG. 43 differs from a case of FIG. 39 in that the protective film 23191 or the like is not formed on the surface in which the sensor die 23021 and the logic die 23024 are bonded together.

The solid-state imaging element 23020 of FIG. 43 is configured by overlaying the sensor die 23021 and the logic die 23024 to have the wirings 23110 and 23170 in direct contact with each other, and then directly bonding the wirings 23110 and 23170 by heating while applying a necessary weight.

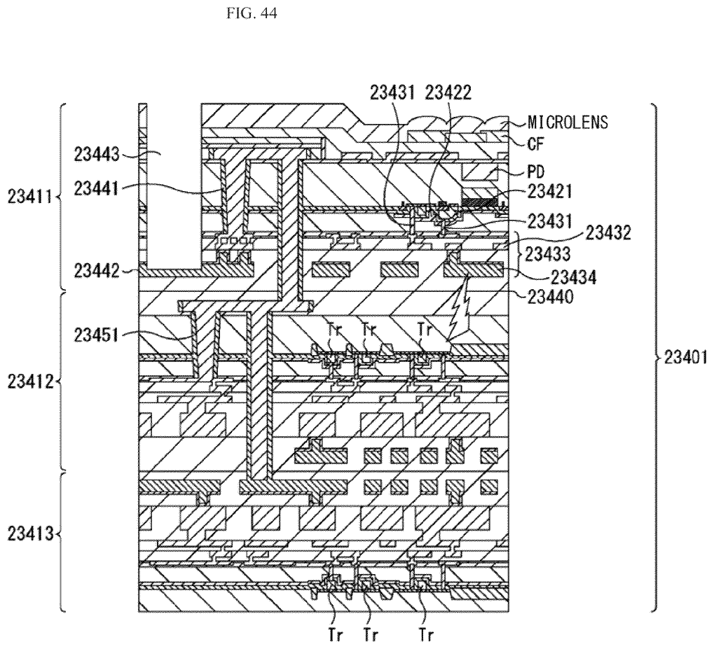

FIG. 44 is a cross-sectional view illustrating another configuration example of a solid-state imaging element of a laminated type to which the technique of the present disclosure is applicable.

In FIG. 44, a solid-state imaging element 23401 has a three-layer laminated configuration in which three dies including a sensor die 23411, a logic die 23412, and a memory die 23413 are laminated.

For example, the memory die 23413 includes a memory circuit that temporarily holds data necessary for signal processing performed by the logic die 23412.

In FIG. 44, although the logic die 23412 and the memory die 23413 are laminated under the sensor die 23411 in the order, it is possible to laminate the logic die 23412 and the memory die 23413 in reverse order, that is, in an order of the memory die 23413 and the logic die 23412 under the sensor die 23411.

It is to be noted that in FIG. 44, the sensor die 23411 includes a PD that serves as a photoelectric conversion section for a pixel and a source/drain region of the pixel Tr.

A gate electrode is formed around the PD via a gate insulating film, and the gate electrode and a paired source/drain region is included in a pixel Tr23421 and a pixel Tr23422.

The pixel Tr23421 adjacent to the PD is the transfer Tr, and one of the paired source/drain region included in the pixel Tr23421 is the FD.

In addition, the sensor die 23411 includes an interlayer insulating film, and the interlayer insulating film has a contact hole. In the contact hole, a coupling conductor 23431 that is to be coupled to the pixel Tr 23421 and the pixel Tr 23422 is formed.

Furthermore, the sensor die 23411 includes a wiring layer 23433 in which a plurality of layers of wiring 23432 to be coupled to each coupling conductor 23431 is formed.

In addition, in a bottom layer of the wiring layer 23433 of the sensor die 23411, an aluminum pad 23434 that serves as an electrode for external coupling is formed. In other words, in the sensor die 23411, the aluminum pad 23434 is formed at a position closer to a bonding surface 23440 with the logic die 23412 than to the wiring 23432. The aluminum pad 23434 is used as one end of the wiring related to signal input and output to and from an outside.

Furthermore, the sensor die 23411 includes a contact 23441 that is used for electrical coupling with the logic die 23412. The contact 23441 is also coupled to a contact 23451 of the logic die 23412 as well as to an aluminum pad 23442 of the sensor die 23411.

Then, the sensor die 23411 has a pad hole 23443 from the back surface side (upper side) of the sensor die 23411 to reach the aluminum pad 23442.

The technique of the present disclosure is applicable to the solid-state imaging element as described above. For example, the plurality of pixel drive lines 23 and the plurality of vertical signal lines 24 as described earlier may be provided in the wiring 23110 or the wiring layer 23161. In this case, it is possible to reduce interwiring capacitance by forming an air gap G as illustrated in FIG. 1 between the plurality of vertical signal lines 24. In addition, it is possible to reduce variation in wiring capacitance by suppressing an increase in interwiring capacitance.

### 6. Practical Application Examples

### Practical Application Example 1

The technique of the present disclosure (the present technology) is applicable to a variety of products. For example, the technique of the present disclosure may be realized as a device mounted on any type of mobile body, such as a car, an electric vehicle, a hybrid electric vehicle, a motorcycle, a bicycle, a personal mobility vehicle, an airplane, a drone, a ship, or a robot.

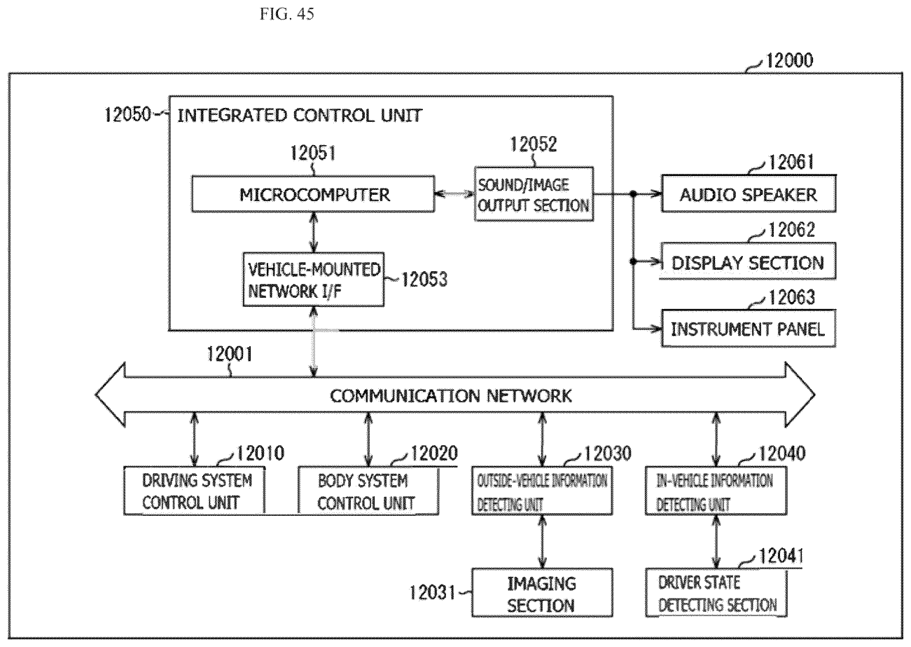

FIG. 45 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 45, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 45, an audio speaker 12061, a display section 12062, and an instrument panel 12063 are illustrated as the output device. The display section 12062 may, for example, include at least one of an on-board display and a head-up display.

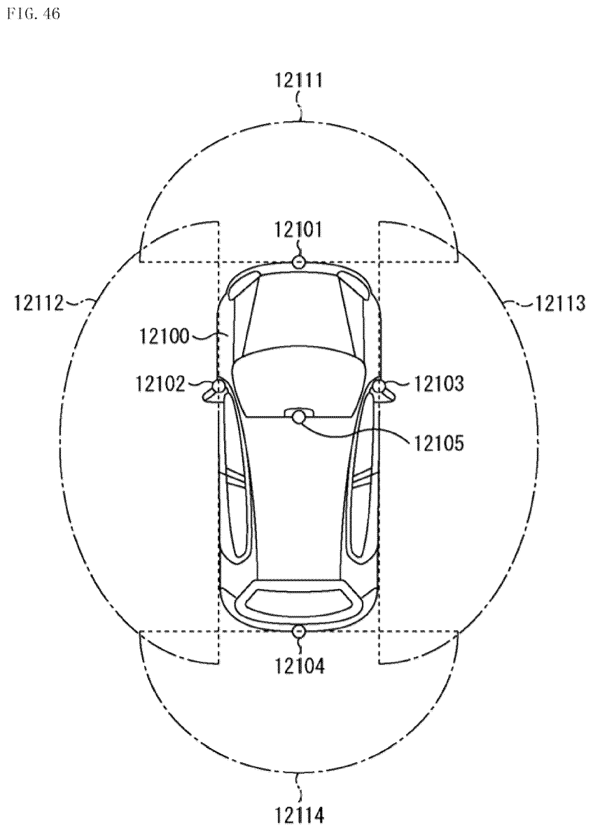

FIG. 46 is a diagram depicting an example of the installation position of the imaging section 12031.

In FIG. 46, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 46 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Some examples of a mobile body control system to which the technique of the present disclosure is applicable have been described above. The technique of the present disclosure is applicable to the imaging section 12031 in the configuration described above. Specifically, it is possible to apply the imaging element 1 according to the above first to third embodiments and the modification examples 1 to 11 thereof to the imaging section 12031. Applying the technique of the present disclosure to the imaging section 12031 makes it possible to obtain a high-definition captured image with less noise, thus making it possible to perform highly accurate control using a captured image in a mobile body control system.

### Practical Application Example 2

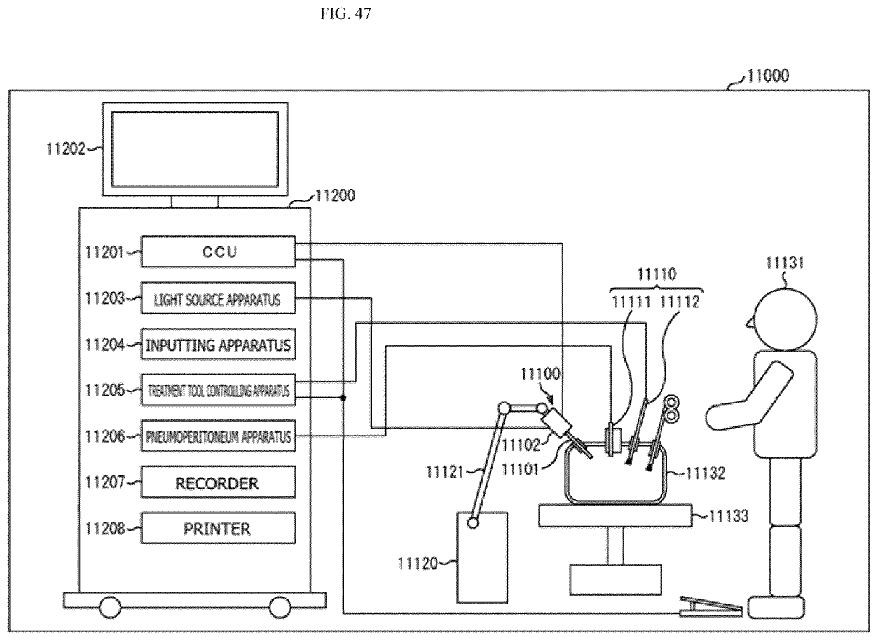

FIG. 47 is a view depicting an example of a schematic configuration of an endoscopic surgery system to which the technology according to an embodiment of the present disclosure (present technology) can be applied.

In FIG. 47, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

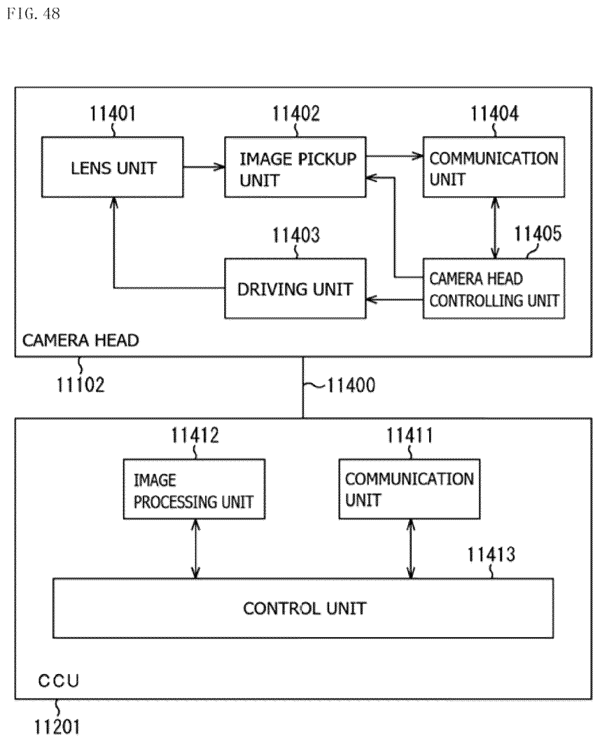

FIG. 48 is a block diagram depicting an example of a functional configuration of the camera head 11102 and the CCU 11201 depicted in FIG. 47.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

Some examples of an endoscopic surgery system to which the technique of the present disclosure is applicable have been described above. Of the configuration described above, the technique of the present disclosure is preferably applicable to the image pickup unit 11402 provided in the camera head 11102 of the endoscope 11100. Applying the technique of the present disclosure to the image pickup unit 11402 allows the image pickup unit 11402 to be smaller or higher definition, thus making it possible to provide a smaller or higher resolution endoscope 11100.

Although the present disclosure has been described above with reference to the first to the third embodiments and the modification examples 1 to 11, application examples, and practical application examples thereof, the present disclosure is not limited to the above embodiments, etc. and various applications and modifications are possible. For example, in the above embodiments, etc. an example has been illustrated in which when processing an inside of the opening H2, the resist film 131 is formed on the barrier film 121 to process the insulating film 111 between a plurality of wirings, but the present disclosure is not limited to this. For example, the insulating film 111 may be processed using a stacked film configuration such as a SMAP method (Stacked Mask Process).

In addition, in the above embodiments, etc., an example in which the plurality of pixel drive lines 23 extends in a row direction and the plurality of vertical signal lines extends in a column direction has been described, but both the pixel drive lines 23 and the vertical signal lines may extend in the same direction. Furthermore, it is possible to change the direction of extension of the pixel drive lines 23 as appropriate, such as in a vertical direction.

In addition, in the above embodiments, etc., the present technology has been described with reference to an example of an imaging element having a three-dimensional configuration, but the present technology is not limited to this. The present technology is applicable to any large scale integrated (LSI) semiconductor device of the three-dimensional laminated type.

It is to be noted that the effects described herein are merely examples. The effects of the present disclosure are not limited to the effects described herein. The present disclosure may have effects other than those described herein.

It is to be noted that it is possible for the present disclosure to have the following configuration. According to the present technology with respect to the following configuration, a first air gap is formed between a plurality of wirings extending in one direction and a second air gap is further formed above the first air gap, thereby reducing a capacitance between the wirings extending in one direction. Thus, it is possible to reduce an overall wiring capacitance.

(1)

An imaging element including:
a wiring layer including a plurality of wirings, the plurality of wirings extending in one direction;
a barrier film laminated on the wiring layer, the barrier film having an end surface above one of the plurality of wirings; and
a first insulating film laminated on the wiring layer and the barrier film,
the imaging element having
a first air gap between the plurality of wirings adjacent to each other, the first air gap being provided by the first insulating film, and
a second air gap provided above the first air gap.
   (2)

The imaging element according to (1), in which
the second air gap has a smaller volume than the first air gap.
   (3)

The imaging element according to (1) or (2), further including a second insulating film, the second insulating film being provided between the first insulating film and the barrier film and continuously covering an upper surface and a side surface of the plurality of wirings.

(4)

The imaging element according to any one of (1) to (3), further including a third insulating film, the third insulating film being provided on the first insulating film, in which
the third insulating film forms the second air gap.
   (5)

The imaging element according to (4), in which
the first insulating film and the third insulating film have a same material composition.
   (6)

The imaging element according to (4) or (5), in which
the third insulating film is an oxide film having a lower step coverage than the first insulating film.
   (7)

The imaging element according to any one of (1) to (6), in which
the plurality of wirings has a side surface and a bottom surface covered by a barrier metal.
   (8)

The imaging element according to (7), in which
the barrier metal covering the side surface of the plurality of wirings having the first air gap therebetween is partially retracted toward the bottom surface, to form a step on the side surface of the plurality of wirings.
   (9)

The imaging element according to any one of (1) to (8), in which
the first insulating film has an unevenness above the plurality of wirings.
   (10)

The imaging element according to any one of (1) to (9), in which
the first insulating film includes a low dielectric material having a relative permittivity k of 3.0 or less.
   (11)

The imaging element according to any one of (4) to (10), in which
the first insulating film and the third insulating film are each selected from tetraethoxysilane-based silicon oxide, carbon-containing silicon oxide, and monosilane-based silicon oxide.
   (12)

The imaging element according to any one of (1) to (11), further including a first conductive film, the first conductive film being directly opposed to at least a portion of the plurality of wirings with the first insulating film therebetween.

(13)

The imaging element according to (12), in which
the first conductive film is electrically coupled to a portion of the plurality of wirings via a coupling section, the coupling section penetrating through the first insulating film.
   (14)

The imaging element according to (12) or (13), further including:
a first substrate including a first semiconductor substrate and a multilayer wiring layer, the first semiconductor substrate having a sensor pixel that performs photoelectric conversion, and the multilayer wiring layer having the first conductive film buried therein; and
a second substrate including a second semiconductor substrate and a multilayer wiring layer, the second semiconductor substrate having a logic circuit that processes a pixel signal, the pixel signal being based on an electric charge outputted from the sensor pixel, and the multilayer wiring layer having a second conductive film buried therein, in which
the first substrate and the second substrate are electrically coupled to each other by bonding the first conductive film and the second conductive film.
   (15)

A method of manufacturing an imaging element, including:
forming a wiring layer including a plurality of wirings, the plurality of wirings extending in one direction;
forming a barrier film on the wiring layer;
causing the wiring layer to have a first opening in a predetermined region thereof, the wiring layer having the first opening between the barrier film and the plurality of wirings adjacent to each other;
forming a first insulating film, thereby forming a first air gap between the plurality of wirings adjacent to each other; and
forming a third insulating film, thereby forming a second air gap above the first air gap.
   (16)

The method of manufacturing an imaging element according to (15), in which
the first insulating film and the third insulating film are formed using a chemical vapor deposition method.
   (17)

The method of manufacturing an imaging element according to (16), in which
the third insulating film is formed under a higher pressure condition than in the forming of the first insulating film.
   (18)

A method of manufacturing an imaging element, including:
forming a wiring layer including a plurality of wirings, the plurality of wirings having a side surface and a bottom surface covered by a barrier metal and extending in one direction;
forming a barrier film on the wiring layer;
causing the wiring layer to have a first opening while partially retracting the barrier metal in a predetermined region of the wiring layer, the wiring layer having the first opening between the barrier film and the plurality of wirings adjacent to each other, and the barrier metal covering the side surface of the plurality of wirings exposed by the first opening;
forming a second insulating film, the second insulating film covering an upper surface and a side surface of the plurality of wirings; and
forming a first insulating film, thereby forming a first air gap and a second air gap, the first air gap being formed between the plurality of wirings adjacent to each other, and the second air gap being formed above the first air gap.

The present application claims the benefit of Japanese Priority Patent Application JP2022-002479 filed with the Japan Patent Office on Jan. 11, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging element, comprising:
a wiring layer including a plurality of wirings, the plurality of wirings extending in one direction;
a barrier film laminated on the wiring layer, the barrier film having an end surface above one of the plurality of wirings; and
a first insulating film laminated on the wiring layer and the barrier film,
the imaging element having
a first air gap between the plurality of wirings adjacent to each other, the first air gap being provided by the first insulating film, and
a second air gap provided above the first air gap.

2. The imaging element according to claim 1, wherein
the second air gap has a smaller volume than the first air gap.

3. The imaging element according to claim 1, further comprising a second insulating film, the second insulating film being provided between the first insulating film and the barrier film and continuously covering an upper surface and a side surface of the plurality of wirings.

4. The imaging element according to claim 1, further comprising a third insulating film, the third insulating film being provided on the first insulating film, wherein
the third insulating film forms the second air gap.

5. The imaging element according to claim 4, wherein
the first insulating film and the third insulating film have a same material composition.

6. The imaging element according to claim 4, wherein
the third insulating film is an oxide film having a lower step coverage than the first insulating film.

7. The imaging element according to claim 1, wherein
the plurality of wirings has a side surface and a bottom surface covered by a barrier metal.

8. The imaging element according to claim 7, wherein
the barrier metal covering the side surface of the plurality of wirings having the first air gap therebetween is partially retracted toward the bottom surface, to form a step on the side surface of the plurality of wirings.

9. The imaging element according to claim 1, wherein
the first insulating film has an unevenness above the plurality of wirings.

10. The imaging element according to claim 1, wherein
the first insulating film includes a low dielectric material having a relative permittivity k of 3.0 or less.

11. The imaging element according to claim 4, wherein
the first insulating film and the third insulating film are each selected from tetraethoxysilane-based silicon oxide, carbon-containing silicon oxide, and monosilane-based silicon oxide.

12. The imaging element according to claim 1, further comprising a first conductive film, the first conductive film being directly opposed to at least a portion of the plurality of wirings with the first insulating film therebetween.

13. The imaging element according to claim 12, wherein
the first conductive film is electrically coupled to a portion of the plurality of wirings via a coupling section, the coupling section penetrating through the first insulating film.

14. The imaging element according to claim 12, further comprising:
a first substrate including a first semiconductor substrate and a multilayer wiring layer, the first semiconductor substrate having a sensor pixel that performs photoelectric conversion, and the multilayer wiring layer having the first conductive film buried therein; and
a second substrate including a second semiconductor substrate and a multilayer wiring layer, the second semiconductor substrate having a logic circuit that processes a pixel signal, the pixel signal being based on an electric charge outputted from the sensor pixel, and the multilayer wiring layer having a second conductive film buried therein, wherein
the first substrate and the second substrate are electrically coupled to each other by bonding the first conductive film and the second conductive film.

15. A method of manufacturing an imaging element, comprising:
forming a wiring layer including a plurality of wirings, the plurality of wirings extending in one direction;
forming a barrier film on the wiring layer;
causing the wiring layer to have a first opening in a predetermined region thereof, the wiring layer having the first opening between the barrier film and the plurality of wirings adjacent to each other;
forming a first insulating film, thereby forming a first air gap between the plurality of wirings adjacent to each other; and
forming a third insulating film, thereby forming a second air gap above the first air gap.

16. The method of manufacturing an imaging element according to claim 15, wherein
the first insulating film and the third insulating film are formed using a chemical vapor deposition method.

17. The method of manufacturing an imaging element according to claim 16, wherein
the third insulating film is formed under a higher pressure condition than in the forming of the first insulating film.

18. A method of manufacturing an imaging element, comprising:
forming a wiring layer including a plurality of wirings, the plurality of wirings having a side surface and a bottom surface covered by a barrier metal and extending in one direction;
forming a barrier film on the wiring layer;
causing the wiring layer to have a first opening while partially retracting the barrier metal in a predetermined region of the wiring layer, the wiring layer having the first opening between the barrier film and the plurality of wirings adjacent to each other, and the barrier metal covering the side surface of the plurality of wirings exposed by the first opening;
forming a second insulating film, the second insulating film covering an upper surface and a side surface of the plurality of wirings; and
forming a first insulating film, thereby forming a first air gap and a second air gap, the first air gap being formed between the plurality of wirings adjacent to each other, and the second air gap being formed above the first air gap.
